(19) United States
(12) Patent Application Publication
(10) Pub. No.: US 2023/0358975 A1
(43) Pub. Date: Nov. 9, 2023

(54) INTEGRATED OPTICAL MICROELECTRONIC MECHANICAL SYSTEMS DEVICES AND METHODS

(71) Applicants: NIHARIKA KOHLI, MONTREAL (CA); MICHAEL MENARD, VERDUN (CA); FREDERIC NABKI, MONTREAL (CA); SURAJ SHARMA, MONTREAL (CA)

(72) Inventors: NIHARIKA KOHLI, MONTREAL (CA); MICHAEL MENARD, VERDUN (CA); FREDERIC NABKI, MONTREAL (CA); SURAJ SHARMA, MONTREAL (CA)

(21) Appl. No.: 18/004,909

(22) PCT Filed: Jul. 9, 2021
(86) PCT No.: PCT/CA2021/050940

§ 371 Date: Jan. 10, 2023

Related U.S. Application Data
(60) Provisional application No. 63/050,351, filed on Jul. 10, 2020.

(51) Int. Cl. G02B 6/42; G02F 1/01; G02F 1/21; B81B 3/00

(52) U.S. Cl. CPC G02B 6/421; G02F 1/0142; G02B 6/4213; G02F 1/212; B81B 3/0062; B81B 2201/047; B81B 2201/033; B81B 2203/055

(57) ABSTRACT

Silicon photonics provides an attractive platform for optoelectronic integrated circuits (OEICs) exploiting hybrid or monolithic integration with or without concurrent integration of microelectromechanical systems (MEMS) and/or CMOS electronic. Such OEICs offering optical component solutions across multiple applications from optical sensors through to optical networks operating upon one or more wavelengths. Accordingly, various silicon photonic building blocks are required in order to provide a toolkit for a circuit designer to exploit OEICs where these building blocks must address specific aspects of OEICs such as polarisation dependency of the optical waveguides. Accordingly, the inventors have established designs for:
polarisation rotators with MEMS based tuning to allow the dual polarisations from a polarisation splitter to be managed by an OEIC operating upon a single polarisation;
analog or digital phase shifts with MEMS actuation for switches, attenuators etc.; and
passband filters with MEMS tuning.

### CROSS-REFERENCE TO RELATED APPLICATIONS

This application claims the benefit of priority as a 371 National Phase Entry of PCT/CA2021/050940 filed Jul. 9, 2021; which itself claims the benefit of priority from U.S. Provisional patent application 63/050,351 filed Jul. 10, 2020.

### FIELD OF THE INVENTION

This invention is directed to silicon photonics and more particularly to silicon photonic building blocks exploiting microelectromechanical systems (MEMS) for control and/or tuning providing polarisation rotators, analog and digital phase shifters with MEMS actuation and passband filters.

### BACKGROUND OF THE INVENTION

Optical networking is a means of communication that uses signals encoded in light to transmit information in various types of telecommunications networks. These include limited range local-area networks (LAN) or wide-area networks (WAN), which cross metropolitan and regional areas as well as long-distance national, international and transoceanic networks. Optical networks typically employ optical amplifiers, lasers, modulators, optical switches and wavelength division multiplexing (WDM) to transmit large quantities of data, generally across fiber-optic cables. Because it is capable of achieving extremely high bandwidth, it is an enabling technology for the Internet and telecommunication networks that transmit the vast majority of all human and machine-to-machine information today. Optical networks are also employed in other applications such as storage area networks and data centers for optical interconnections at rack/server level but these techniques can extend to optical interconnections within a server, between circuits on a circuit board etc.

Optoelectronic integrated circuits exploiting hybrid or monolithic integration offer solutions for the different optical components required. To date hybrid integration approaches have been dominant with semiconductor emitters and detectors with bulk and micro-optic solutions for filters, switches, attenuators, etc. and integrated optical modulators either integrated with the semiconductor emitter or externally coupled. However, silicon photonics offers several benefits making it an attractive material system for monolithic integration. Firstly, the material is transparent to the wavelengths commonly used for optical communication systems (namely 1300-1600 nm), it supports standard Complementary Metal-Oxide Semiconductor (CMOS) processing techniques, and it is CMOS-compatible allowing processing of monolithic opto-electronic devices. Accordingly, silicon photonics offers a material system for optical componentry offering higher speed, increased functionality, lower electrical power and smaller footprint, all at a lower cost. Further, developments of silicon based light-emitting diodes offer a path to optical emitter integration other than hybrid integration of semiconductor devices.

Accordingly, various silicon photonic building blocks are required in order to provide a toolkit for a circuit designer to build optoelectronic integrated circuits (OEICs) in a similar manner as they work with libraries of standard electronic building blocks today. Further, other silicon photonic building blocks are required to address specific aspects of OEICs not present within electronics such as polarisation dependency of the optical waveguides, OEIC building blocks etc.

In addition to silicon photonics and CMOS electronics silicon offers the further ability to integrated microelectromechanical systems (MEMS) elements within the circuits to provide additional functionality. Within the following specification the inventors outline the establishment of several silicon photonic building blocks including polarisation rotators with MEMS based tuning, analog and digital phase shifters with MEMS actuation and passband filters with MEMS tuning.

Other aspects and features of the present invention will become apparent to those ordinarily skilled in the art upon review of the following description of specific embodiments of the invention in conjunction with the accompanying figures.

### SUMMARY OF THE INVENTION

It is an object of the present invention to mitigate limitations in the prior art relating to integrated optical microelectromechanical systems and more particularly to establishing structures and methods for implementing phase shifting elements within integrated optical microelectromechanical systems and integrated optical microelectromechanical system based devices exploiting such phase shifting elements.

In accordance with an embodiment of the invention there is provided an optical device comprising:
an input waveguide section;
an output waveguide section; and
a central waveguide section disposed between the input waveguide section and the output waveguide section; wherein
a cladding of the central waveguide section is asymmetrically disposed with respect to a core of the central waveguide section such that the core is close to a side wall of the cladding.

In accordance with an embodiment of the invention there is provided an optical device comprising:
a waveguide section comprising:
an input waveguide section;
an output waveguide section; and
a central waveguide section of a predetermined length disposed between the input waveguide section and the output waveguide section having a cladding disposed with respect to a core of the central waveguide section such that the core is close to a side wall of the cladding; and
a microelectromechanical systems (MEMS) element comprising:
a suspended platform;
a MEMS actuator coupled to the suspended platform; and
a perturbation element disposed at a distal end of the suspended platform to that coupled to the MEMS actuator; wherein
the perturbation element is disposed beside the side wall of the cladding to which the core is close.

In accordance with an embodiment of the invention there is provided a method of providing a waveguide polarisation rotator comprising:
providing a central waveguide section of a predetermined length disposed between an input waveguide section and an output waveguide section having a cladding disposed with respect to a core of the central waveguide section such that the core is close to a side wall of the cladding; and
providing a microelectromechanical systems (MEMS) element comprising:
a suspended platform;
a MEMS actuator coupled to the suspended platform; and
a perturbation element disposed at a distal end of the suspended platform to that coupled to the MEMS actuator; wherein
the perturbation element is disposed beside the side wall of the cladding to which the core is close.

In accordance with an embodiment of the invention there is provided an optical device comprising:
a waveguide section comprising:
   an input waveguide section;
   an output waveguide section; and
   a central waveguide section of a predetermined length disposed between the input waveguide section and the output waveguide section having a cladding disposed with respect to a core of the central waveguide section such that the core is either close to a side wall of the cladding or exposed through the cladding; and
a microelectromechanical systems (MEMS) element comprising:
   a suspended platform;
   a MEMS actuator coupled to the suspended platform; and
   a perturbation element disposed at a distal end of the suspended platform to that coupled to the MEMS actuator; wherein
the perturbation element is disposed beside the side wall of the cladding to which the core is close.

In accordance with an embodiment of the invention there is provided a method of providing an optical waveguide phase shift element comprising:
providing a waveguide section comprising:
   an input waveguide section;
   an output waveguide section; and
   a central waveguide section of a predetermined length disposed between the input waveguide section and the output waveguide section having a cladding disposed with respect to a core of the central waveguide section such that the core is exposed through the cladding; and
providing a microelectromechanical systems (MEMS) element comprising:
   a suspended platform;
   a MEMS actuator coupled to the suspended platform; and
   a perturbation element disposed at a distal end of the suspended platform to that coupled to the MEMS actuator; wherein
the perturbation element is disposed beside the side wall of the cladding to which the core is close; and
the core of the central waveguide section overhangs the cladding.

In accordance with an embodiment of the invention there is provided an optical device comprising:
a tunable optical filter comprising:
a Mach-Zehnder interferometer (MZI);
a first ring resonator; and
a second ring resonator disposed between an arm of the MZI and the first ring resonator such that optical signals coupled to the MZI are only coupled to the first ring resonator via the second ring resonator; wherein
a bandwidth of the tunable optical filter is established in dependence upon a first coupling strength between the arm of the MZI and a second coupling strength between the first ring resonator and the second ring resonator;
a shape of the passband of the tunable optical filter is established in dependence upon the first coupling strength and the second coupling strength; and
the centre wavelength of the tunable optical filter is established in dependence upon a first phase shift within the MZI, a second phase shift within the first ring resonator and a second phase shift within the second ring resonator.

In accordance with an embodiment of the invention there is provided a method comprising: dynamically establishing a bandwidth, a passband shape and a center wavelength of an optical filter; wherein
the optical filter comprises a Mach-Zehnder interferometer (MZI), a first ring resonator, and a second ring resonator disposed between an arm of the MZI and the first ring resonator such that optical signals coupled to the MZI are only coupled to the first ring resonator via the second ring resonator;
the bandwidth of the optical filter is established in dependence upon a first coupling strength between the arm of the MZI and a second coupling strength between the first ring resonator and the second ring resonator;
the passband shape of the optical filter is established in dependence upon the first coupling strength and the second coupling strength; and
the centre wavelength of the optical filter is established in dependence upon a first phase shift within the MZI, a second phase shift within the first ring resonator and a second phase shift within the second ring resonator.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIGS. 1A and 1B depict top and cross-section views of a polarization rotator according to an embodiment of the invention with a section of side cladding etched in the central section;

FIG. 2A depicts simulated transmission versus propagation length in a polarization rotator according to an embodiment of the invention;

FIGS. 2B and 2C depict the E_{y} and E_{Z} field distributions in x-y as a function of propagation length for polarization rotator according to an embodiment of the invention;

FIG. 3A depicts the simulated TE polarization fraction versus side cladding width;

FIG. 3B depicts the effect of perturbations for TE polarization fractions of the two hybrid modes induced by an oxide block disposed adjacent to a polarization rotator according to an embodiment of the invention allowing post-fabrication via a microelectromechanical systems (MEMS) tuning mechanism;

FIG. 3C depicts optical simulations of the two hybrid modes supported by the polarisation rotator according to embodiments of the invention showing 45° rotation of eigenaxes;

FIG. 4 depicts a cross-section of a polarisation rotator according to an embodiment of the invention wherein the polarisation rotator is tuning via an oxide block using a MEMS actuator;

FIG. 5 depicts cross-section and plan views of a MEMS tunable Mach-Zehnder interferometer (MZI) according to an embodiment of the invention;

FIG. 6 depicts analog MEMS tunable MZI designs according to embodiments of the invention exploiting linear and non-linear springs;

FIGS. 7A and 7B depicts a digital MEMS tunable MZI according to an embodiment of the invention exploiting parallel plate actuators at 250 nm and 0 nm gaps respectively;

FIG. 8 depicts a digital MEMS tunable MZI exploiting a binary configuration according to an embodiment of the invention;

FIG. 9 depicts an analog MEMS actuator for a tunable MZI exploiting a linear serpentine spring system according to an embodiment of the invention;

FIG. 10 depicts a simulated actuation curve for 10 μm wide silicon beams within a linear serpentine spring system for a MEMS tunable MZI according to an embodiment of the invention;

FIG. 11 depicts a simulated actuation curve for 15 μm wide silicon beams within a linear serpentine spring system for a MEMS tunable MZI according to an embodiment of the invention;

FIG. 12 depicts an analog MEMS actuator for a tunable MZI with non-linear serpentine spring system according to an embodiment of the invention;

FIGS. 13A and 13B depict simulation results for the spring constant curve for the non-linear serpentine spring system according to an embodiment of the invention as depicted in FIG. 12 with 5 μm and 10 μm wide silicon beams;

FIG. 14 depicts an exemplary analog MEMS actuator layout employed in development of MEMS actuators for MEMS tunable MZI devices according to embodiments of the invention;

FIG. 15 depicts designs for digital MEMS tunable MZIs according to embodiments of the invention at zero gap between the MZI arm and the perturbation waveguide;

FIG. 16 depicts a design for a digital MEMS tunable MZI according to an embodiment of the invention with zero gap phase tuning between the MZI;

FIG. 17 depicts a design for a digital MEMS tunable MZI according to an embodiment of the invention with 250 nm gap phase tuning with mechanical stoppers;

FIG. 18 depicts a design for a digital MEMS tunable MZI according to an embodiment of the invention with 250 nm gap phase tuning and integrated mechanical stoppers;

FIGS. 19A and 19B depict a zero gap digital MEMS actuator layout employed in development of devices according to embodiments of the invention;

FIGS. 20A and 20B depict 250 nm gap digital MEMS actuator layout employed in development of devices according to embodiments of the invention with 12 tuning actuators and 9 tuning actuators respectively;

FIGS. 21A and 21B depict a mechanical stopper design according to an embodiment of the invention together with static structural simulation results for the applied force on the stopper;

FIG. 22 depicts a zero gap binary MEMS actuator layout employed in the development of devices according to embodiments of the invention;

FIGS. 23A and 23B depict a 250 nm gap binary MEMS actuator layout employed in the development of devices according to embodiments of the invention together with actuator simulation results;

FIG. 24A depicts top and cross-sectional views of a zero gap MEMS tunable MZI device according to an embodiment of the invention where the MZI arm has minimum side cladding and is perturbed with a perturbation waveguide;

FIG. 24B depicts top and cross-sectional views of a zero gap MEMS tunable MZI device according to an embodiment of the invention where the MZI arm with side cladding is perturbed by a corresponding perturbation waveguide with minimum side cladding;

FIG. 24C depicts top and cross-sectional views of a zero gap MEMS tunable MZI device according to an embodiment of the invention where the MZI arm with side cladding is perturbed by a corresponding perturbation waveguide with side cladding;

FIG. 25 depicts simulated perturbation analysis for phase shift tuning according to an embodiment of the invention between a MZI arm with varied side cladding and a perturbation waveguide for varying gaps;

FIG. 26 depicts cross-sectional and top views of a MEMS tunable MZI device according to an embodiment of the invention during a selective silicon oxide removal step resulting in an overhang within the tuning/perturbation region;

FIGS. 27A to 27H depict cross-sectional and top views of an exemplary microfabrication process flow for MEMS tunable MZI devices according to embodiments of the invention;

FIG. 28 depicts a design schematic of a ring resonator assisted MZI (RA-MZI) according to an embodiment of the invention with a first design methodology (Design 1) exploiting parallel coupling between two ring resonators and the MZI with no coupling between the ring resonators and a schematic of the cascaded ring resonators and MZI bus waveguide used in design analysis;

FIG. 29 depicts a design schematic of a ring resonator assisted MZI (RA-MZI) according to an embodiment of the invention with a second design methodology (Design 2) exploiting parallel coupling between two ring resonators and the MZI with coupling between the ring resonators and a schematic of the cascaded ring resonators and MZI bus waveguide used in design analysis;

FIG. 30 depicts a design schematic of a ring resonator assisted MZI (RA-MZI) according to an embodiment of the invention with a third design methodology (Design 3) exploiting serial coupling between two ring resonators and the MZI with coupling between the ring resonators and a schematic of the cascaded ring resonators and MZI bus waveguide used in design analysis;

FIG. 31 depicts simulated wavelength responses for an RA-MZI filter according to embodiment of the invention exploiting the design methodology of Design 2 targeted for a 3 dB bandwidth of 0.14 nm with reference to an RA-MZI filter according to Design 1;

FIG. 32 depicts simulated wavelength responses for an RA-MZI filter according to an embodiment of the invention exploiting the design methodology of Design 3 targeted for a 3 dB bandwidth of 0.14 nm with reference to an RA-MZI filter according to Design 1;

FIGS. 33 and 34 depict simulated wavelength responses for an RA-MZI filter according to an embodiment of the invention exploiting the design methodology of Design 3 for two different coupling strengths;

FIGS. 35 and 36 depict simulated wavelength responses for an RA-MZI filter according to an embodiment of the invention exploiting the design methodology of Design 3 for two different coupling strengths;

FIG. 37A depicts a comparison of measured and simulated TE wavelength responses for a RA-MZI according to an embodiment of the invention exploiting the design methodology of Design 1;

FIG. 37B depicts a comparison of measured and simulated TE wavelength responses for a RA-MZI according to an embodiment of the invention exploiting the design methodology of Design 2;

FIGS. 37C to 37E depict comparisons of measured and simulated TE wavelength responses for a RA-MZI according to an embodiment of the invention exploiting the design methodology of Design 3 for three different waveguide widths;

FIG. 38 depicts a schematic of a RA-MZI filter according to an embodiment of the invention exploiting the design methodology of Design 3 with thermal actuators to tune coupling between the RA-MZI elements;

FIG. 39 depicts a schematic of a RA-MZI filter according to an embodiment of the invention exploiting the design methodology of Design 3 with MEMS actuators to move platforms supporting the ring resonators to tune coupling between the RA-MZI elements; and

FIG. 40 depicts variant structures of optical waveguides supporting perturbation elements according to embodiments of the invention with symmetric or near-symmetric cladding profiles

### DETAILED DESCRIPTION

The present invention is directed to integrated optical microelectromechanical systems and more particularly to establishing structures and methods for implementing phase shifting elements within integrated optical microelectromechanical systems and integrated optical microelectromechanical system based devices exploiting such phase shifting elements.

The ensuing description provides representative embodiment(s) only, and is not intended to limit the scope, applicability, or configuration of the disclosure. Rather, the ensuing description of the embodiment(s) will provide those skilled in the art with an enabling description for implementing an embodiment or embodiments of the invention. It being understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purpose only. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional elements.

A “two-dimensional” waveguide, also referred to as a 2D waveguide or a planar waveguide as used herein may refer to, but is not limited to, an optical waveguide supporting propagation of optical signals within a predetermined wavelength range which does not guide the optical signals laterally relative to the propagation direction of the optical signals.

A “three-dimensional” waveguide, also referred to as a 3D waveguide or a channel waveguide as used herein may refer to, but is not limited to, an optical waveguide supporting propagation of optical signals within a predetermined wavelength range which guides the optical signals laterally relative to the propagation direction of the optical signals.

A “microelectromechanical system” or “microelectromechanical systems” (MEMS) as used herein may refer to, but is not limited to, a miniaturized mechanical and electro-mechanical element which is manufactured using techniques of microfabrication. For example, the MEMS may be implemented in silicon.

A “wavelength division demultiplexer” (WDM DMUX) as used herein may refer to, but is not limited to, an optical device for splitting multiple optical signals of different wavelengths apart which are received on a common optical waveguide, e.g. a waveguide forming part of a photonic integrated circuit or an optical fiber.

A “wavelength division multiplexer” (WDM MUX) as used herein may refer to, but is not limited to, an optical device for combining multiple optical signals of different wavelengths together onto a common optical waveguide, e.g. a waveguide forming part of a photonic integrated circuit or an optical fiber.

A “Mach-Zehnder interferometer” (MZI) as used herein may refer to, but is not limited to, an optical device exploiting phase imbalance between two arms disposed between an input 1×2 or 2×2 3 dB coupler and an output 2×1 or 2×2 3 dB coupler to provide for programmable modulation, attenuation, optical switching or wavelength filtering functions.

Section 1: Polarisation Rotator

As noted above silicon photonics offers a promising technology for reducing the cost structure of the various optical components employed within optical networks as it allows for leveraging the economies of scale of the microelectronics industry as well as the monolithic integration of electronics, e.g. CMOS. However, whilst the single mode optical fibers linking nodes within these networks offer low loss polarization independent transmission lines with low polarization dependent loss and polarization mode dispersion (e.g. ≤0.1ps/km for Corning™ SMF-28) the same is not true for the integrated optical waveguides upon substrates forming the tunable transmitters, tunable receivers, routers, reconfigurable optical add/drop multiplexers (ROADMs), wavelength division multiplexers (WDMs) and optical filters.

Accordingly, within the prior art significant research has been directed to techniques for mitigating polarisation dependent effects of the substrate based optical waveguides through fabrication processes, complex waveguide geometries etc. to provide polarisation independent optical waveguides. In parallel, other research has taken an alternate approach to exploit polarization diverse designs that handle the TE and TM polarizations wherein the increased circuit complexity of duplicate processing with high volume silicon manufacturing is expected to offer lower final circuit costs by exploiting standard fabrication and processing flows rather than bespoke fabrication processes, non-standard process flows, etc. with lower yields.

These issues are significant for existing telecommunication systems but become critical for coherent optical communication systems where data is encoded on both TE and TM polarisations.

An important photonic building block therefore is a polarisation rotator. This allows a received polarisation, e.g. TM, to be converted to another polarisation, e.g. TE, wherein it is processed by the photonic circuit comprising the optical waveguides. In this manner, received TE and TM signals may be parallel processed in the TE polarisation by a photonic circuit rather than requiring that the photonic circuit have parallel paths processing the TE and TM signals thereby reducing material constraints, fabrication constraints, etc.

Within the prior art polarization rotators generally use two methods to perform the rotation from one optical mode to the other optical mode. These are the adiabatic mode evolution and mode interference. Adiabatic mode evolution adiabatically converts the input fundamental TM mode to a higher order TE mode and then convert it to the fundamental TE mode using an appropriate mechanism. Mode interference allows complete transfer of power between the fundamental hybrid modes based upon the beating of these two modes which are tilted by 45 degrees with respect to the eigenaxis. Amongst, the structure employed in mode-interreference are longitudinally periodic modified structures, bend structures, and single section waveguides with asymmetric core structures.

However, adiabatic polarization rotators usually require a long device length to achieve high efficiency. Moreover, in order to exploit the hybrid-modes of the waveguides for polarization rotation, usually an asymmetry is required in the waveguide structure. Within the prior art this asymmetry has been achieved by modifying the thickness of the waveguide, breaking the symmetry of the waveguide cross-section by using a stair-like geometry, changing the material of the upper cladding etc. However, such geometrical constraints and fabrication complexities result in designs unsuitable for mass productions. Accordingly, the inventors have established a novel design wherein the fundamental hybrid modes interfere with each other such that at the appropriate length, the input TE mode is converted to the TM mode and vice-versa. In contrast to the prior art complexities of design and/or manufacturing the novel architecture is implemented with a single etch step. Further, as will become evident the inherent variations of the manufacturing process can be compensated for using electrostatic MEMS tuning.

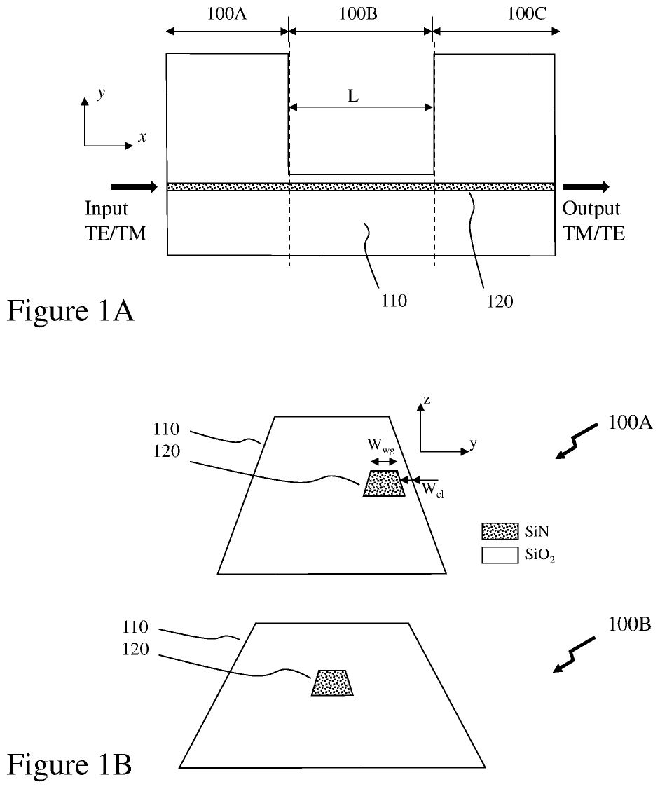

In contrast to the prior art the novel polarisation rotator established by the inventors exploits mode-interference. As noted above, in contrast to prior art mode interference polarisation rotators, the novel polarisation rotator does not require partial etching of the waveguide core, a different top cladding material or exposing the waveguide core to air. Similarly, the novel polarisation rotator does not introduce hybridization in the waveguides by modifying its shape or thickness or both. In contrast, the inventive polarisation rotator exploits partial side cladding removal. With respect to FIGS. 1A to 4 the silicon photonics platform described and depicted is what the inventors refer to as an oxide-nitride-oxide (ONO) waveguide structure with a silicon oxide lower cladding, a silicon nitride waveguide core and an upper silicon oxide cladding, i.e. a SiO₂—Si₃N₄—SiO₂ waveguide structure. However, it would be evident that other waveguide structures may be employed without departing from the scope of the invention.

Accordingly, referring to FIGS. 1A and 1B there are depicted top and cross-sectional views of a polarization rotator according to an embodiment of the invention with a section of side cladding etched. As depicted in FIG. 1A an optical waveguide comprising a core 120 within a cladding 110 is deployed upon a substrate, not depicted for clarity, and propagates from a first region 100A to a second region 100B and therein to a third region 100C. First cross-section 100A in FIG. 1B depicts the cross-section through the second region 100B whilst second cross-section 100B in FIG. 1B depicts the cross-section through the first and third regions 100A and 100C, respectively. Accordingly, for a length, L, the optical waveguide propagates with an asymmetric lateral cladding. Whilst abrupt transitions between the polarisation rotator, second region 100B, and input/output waveguides, first and third regions 100A and 100C respectively, are depicted within FIG. 1A it would be evident that alternate transitions with tapered lateral etch profile from that of the first and third regions 100A and 100C respectively to/from the second region 100B.

Accordingly, initial embodiments of the invention were implemented using the ONO (SiP₂—Si₃N₄—SiO₂) waveguide structure with a core thickness of 435 nm and a top-width, W_{wg}, of 435 nm. Accordingly, fabrication began with the deposition of 3.2 μm of SiO₂ (SiO2) on a Si wafer followed by that of the Si₃N₄ (SiN). The SiN waveguide pattern was then defined using optical lithography followed by dry etching wherein the fabricated SiN core has a trapezoidal shape with a side-wall angle of approximately 80°. In the final step the wafer was covered with another 3.2 μm of SiO2 to form the top cladding, which was etched after patterning with electron beam lithography. The side-angle of the etched cladding based on this fabrication process was 86°. For this waveguide geometry, which is governed by the fabrication process, if the side-clad is etched from one side of the waveguide as shown in first cross-section 100A in FIG. 1B and the remaining width of the side cladding (W_{cl}) is optimized to 157 nm, then two hybrid modes with TE polarization fractions close to 50% are supported by the optical waveguide. This ensures that both modes are equally excited at the input.

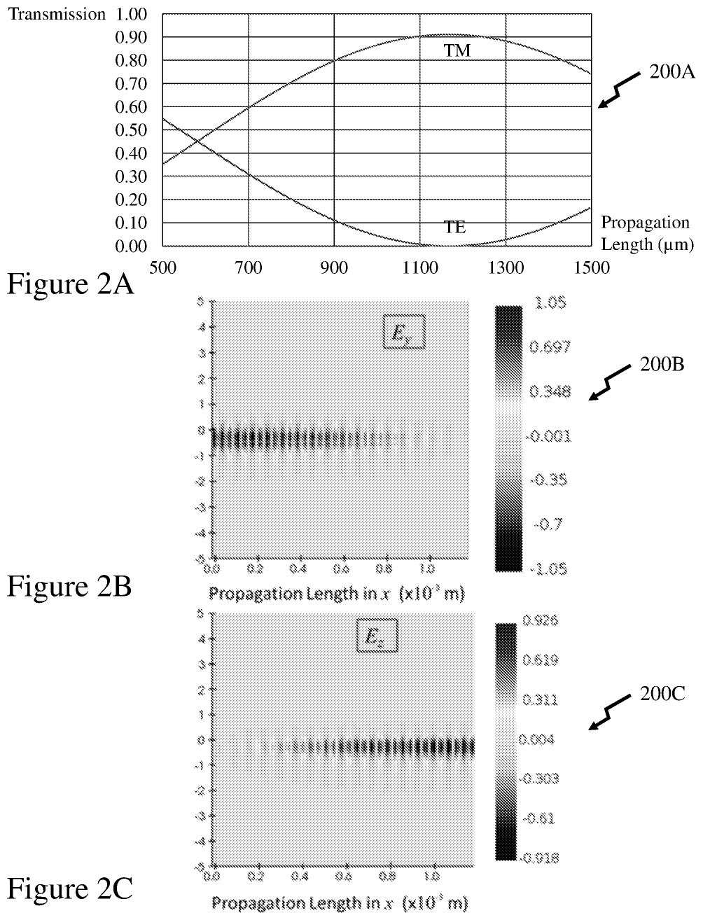

Now referring to FIG. 2A there is depicted a plot of transmission versus the propagation length of the device. At the mode beating length of 1175 μm, the input TE polarization is rotated to the TM polarization state. From simulations, the conversion efficiency, extinction ratio and insertion loss for the polarisation rotator were determined to be 99.99%, 31.1 dB and 0.4 dB, respectively. Accordingly, to the inventor's knowledge, this is the best performance reported for a polarisation rotator based upon the ONO waveguide structure. Since the device is reciprocal in nature, the same performance is obtained if the input polarization is TM instead of TE. FIGS. 2B and 2C show the real part of the field distribution of the E_{y} and E_{z} components, respectively, in the x-y plane sliced at a fixed z located at the center of the waveguide. Accordingly, the rotation of the TE component launched at the input to the TM component at the output is clearly evident.

As the mode beating length is dependent upon the mode indices of the two modes then the performance of the polarisation rotator is sensitive to the width of the SiN waveguide and the side-cladding. Accordingly, for high volume manufacturing upon commercial silicon foundries it would be beneficial for a tuning mechanism to be implementable in conjunction with the polarisation rotator structures to allow for tuning the device to compensate for errors after fabrication. Within the prior art a common tuning mechanism for optical devices is thermo-optic tuning. Thermo-optic tuning has been used to produce phase-shift in devices that produce polarization rotation with a polarization extinction ratio range of 40 dB. However, thermal tuning requires high electrical power consumption and provides undesired thermal cross-talk to adjacent elements of the photonic circuit.

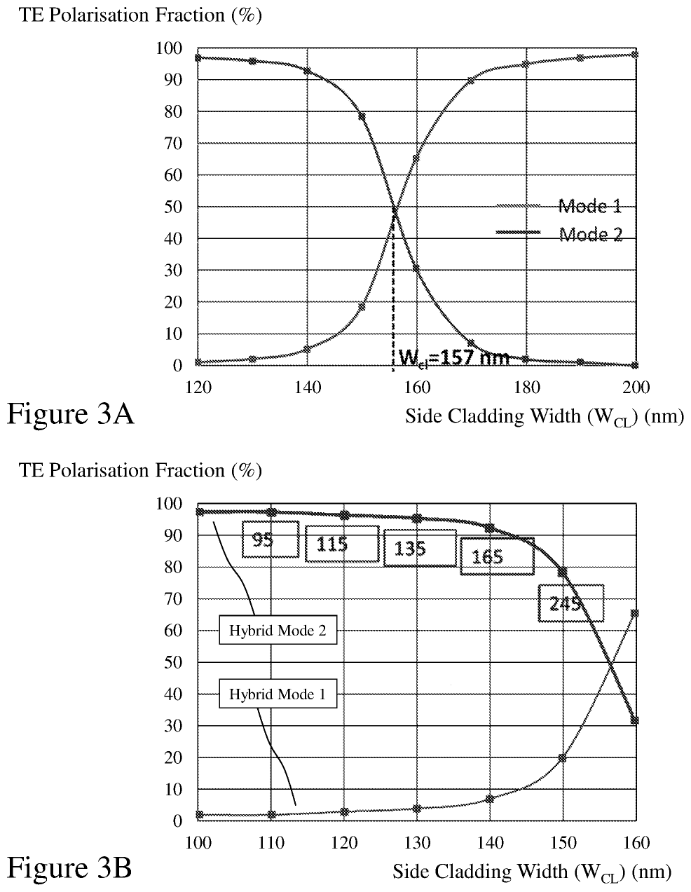

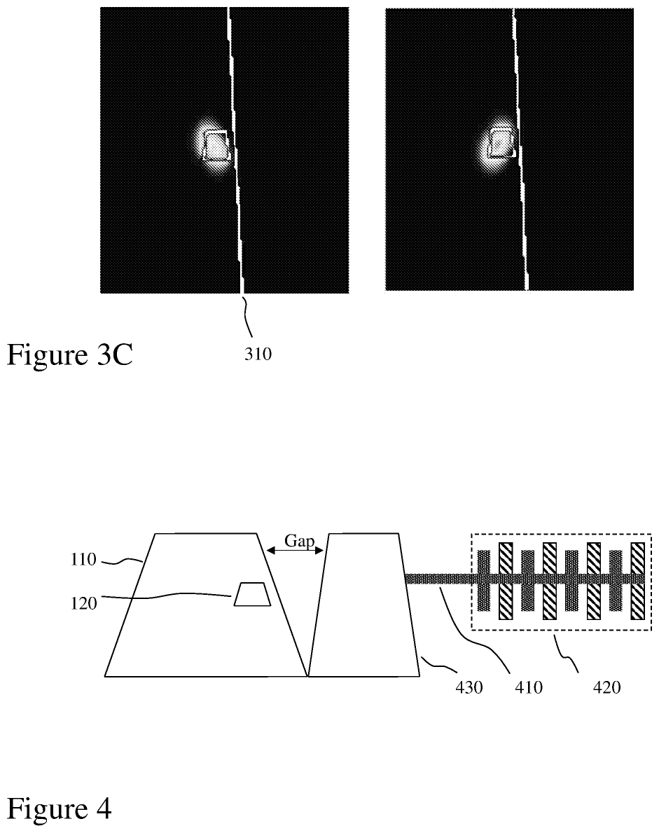

Accordingly, the inventors have established a novel tuning mechanism which exploits electrostatic MEMs actuators thereby avoiding the limitations of thermal tuning. Referring to FIG. 3A there is depicted the simulated results for the TE polarization fractions of the two hybrid modes supported by the optical waveguide within polarisation rotators according to embodiments of the invention showing that a cladding width of 157 nm yields 50% fractions in each mode. FIG. 3B depicts the effect of MEMs tuning on the novel polarisation rotator according to embodiments of the invention. If the central region of the polarisation rotator, second region 100B in FIG. 1A, is perturbed, for example by an oxide block, then as the gap between the polarisation rotator and the oxide block is reduced to a few hundred nanometers as shown in FIG. 4, then the oxide block perturbs the optical waveguide thereby allowing for tuning to compensate for the errors induced from fabrication tolerances.

For cladding widths lower than 157 nm, the first mode is more like a quasi-TM mode and then second mode is more like a quasi-TE mode. However, upon perturbing it, it is evident that tuning of the first two modes is possible to become hybrid with the polarization fractions close to 50%. The values of the gap between the oxide block and polarisation rotator in nanometers are shown in the boxes in FIG. 3B for different cladding widths in order to tune the polarisation rotator back to its hybridized state. Accordingly, it is possible to tune the polarisation rotator to its desired operating point by adjusting the perturbation induced by the oxide block. Electric field intensity simulations of the two hybrid modes supported by the optical waveguide near the cladding sidewall 310 in the polarisation rotator according to embodiments of the invention are depicted in FIG. 3C showing the 45° rotation of the eigenaxes.

Referring to FIG. 4 the oxide block 430 is depicted disposed adjacent to the optical waveguide comprising waveguide core 120 within cladding 110. The oxide block 430 is coupled to a MEMS actuator 420 via a beam 410. Accordingly, the oxide block 430 can be positioned relative to the core 120 using the MEM actuator 420 allowing for post-fabrication tuning of the polarisation rotator. It would be evident that the concepts described and depicted below in respect of phase shifter elements in Section 2 may be employed such that multiple oxide blocks and MEMS actuators may be employed to provide analog or digital control of the tuning applied to the polarisation rotator. Further, such MEMS actuators may employ a latching mechanism to latch the actuator between two or more positions. The number of positions being established according to the design of the latching mechanism, design of tuning structure (e.g. number of oxide blocks, analog versus digital etc.), etc.

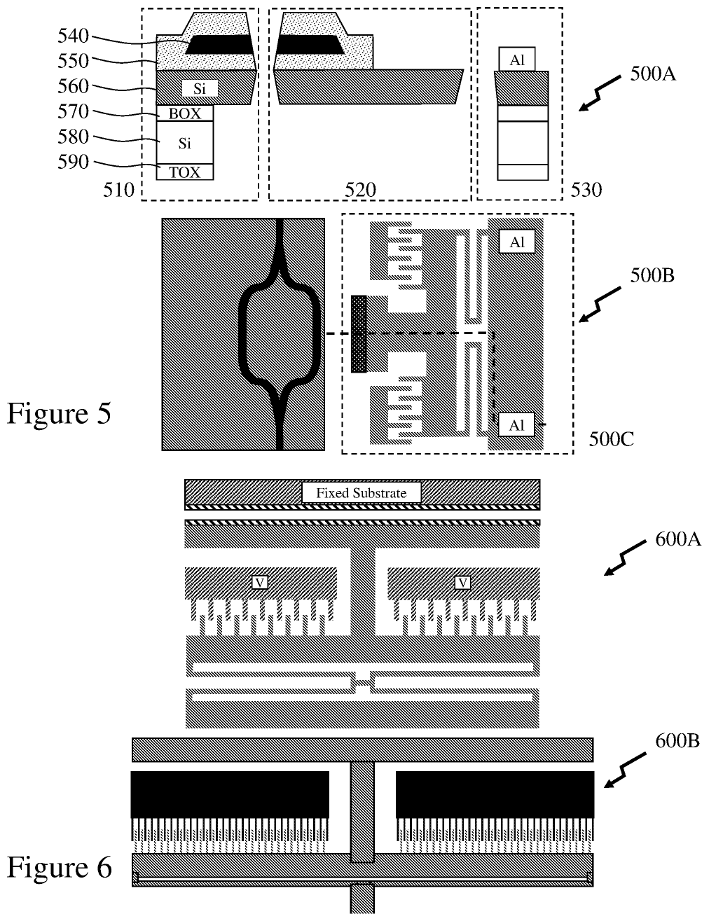

For example, whilst the designs described and depicted with respect to FIGS. 5 to 27H are described and depicted with respect to the concept of phase tuning an arm or arms of a Mach-Zehnder interferometer these concepts may be applied to the provisioning of perturbation elements for tuning a polarisation rotator according to embodiments of the invention. Similarly, whilst FIGS. 3 and 4 are based upon an oxide block it would be evident that within other embodiments the perturbation elements may be ONO stacks in common with the waveguide or formed from the same material stack as the optical waveguide where the optical waveguide exploits alternate waveguide structures/materials.

Section 2: Analog and Digital Mems Based Phase Shifters

Within photonic circuit building blocks such as Mach-Zehnder interferometers (MZIs) a defined phase balance or imbalance is required in order to allow for either symmetric drive or asymmetric drive. As noted above in respect of Section 1 a common approach within the prior art to inducing a static phase shift within an optical waveguide is via the thermo-optic effect. However, as noted this requires high power consumption and one or more of complex control algorithms and complex manufacturing to accommodate/eliminate thermal crosstalk between multiple photonic circuit elements within the same photonic circuit. Accordingly, the inventors have established a series of analog and digital microelectromechanical system (MEMS) based methods for controlled phase shift within optical waveguides and therein within optical circuit elements such as in integrated optical components such as MZIs for example. Beneficially, such novel solutions reduce electrical power consumption, eliminate thermal crosstalk issues, and provide for solutions that can be latched thereby eliminating the requirement for continuous electrical signals applied to the tuning elements.

2A: Overview

Within this Section and with respect to FIGS. 5 to 27H the silicon photonics platform described and depicted is for tuning silicon nitride based optical components employing what the inventors refer to as an oxide-nitride-oxide (ONO) waveguide structure with a silicon oxide lower cladding, a silicon nitride waveguide core and an upper silicon oxide cladding, i.e. a SiO₂—Si₃N₄—SiO₂ waveguide structure. However, it would be evident that other waveguide structures may be employed without departing from the scope of the invention.

In common with the design methodology described and depicted in FIG. 4 for the polarisation rotator the novel phase shifter structures described and depicted with respect to FIGS. 5 to 27H employ an optical waveguide fabricated upon a fixed substrate whilst a perturbation element is fabricated on a MEMS platform. Accordingly, when the perturbation element is brought close to the optical waveguide, e.g. one of the arms of a MZI, by closing the air gap to a few nanometers, the effective refractive index of the optical waveguide changes and a phase shift is produced in the optical signal propagation through the optical waveguide.

FIG. 5 depicts a cross-sectional view 500A along the section line X-X depicted within the plan view 500B. Accordingly, an optical waveguide section 510 is attached to the substrate whilst the perturbation element 520 forms part of MEMS structure wherein the suspended perturbation element 520 is coupled to a MEMS actuator 530. As depicted in the cross-sectional view 500A the optical waveguide within the optical waveguide section 510 and the perturbation element 520 comprise a SiN 540 core within a Tetraethyl Orthosilicate (TEOS) based deposited SiO2 550 cladding upon an upper silicon 560 layer. The upper silicon 550 layer being disposed atop a stack comprising, from bottom to top of a thermal oxide layer (TOX) SiO2 590 atop a silicon substrate (not shown for clarity), a lower silicon layer 580 and a Buried Oxide (BOX) SiO2 570 layer. Accordingly, etching of the TOX SiO₂ 570, lower silicon layer 580- and BOX SiO2 570 releases the upper silicon layer 560 from the silicon substrate.

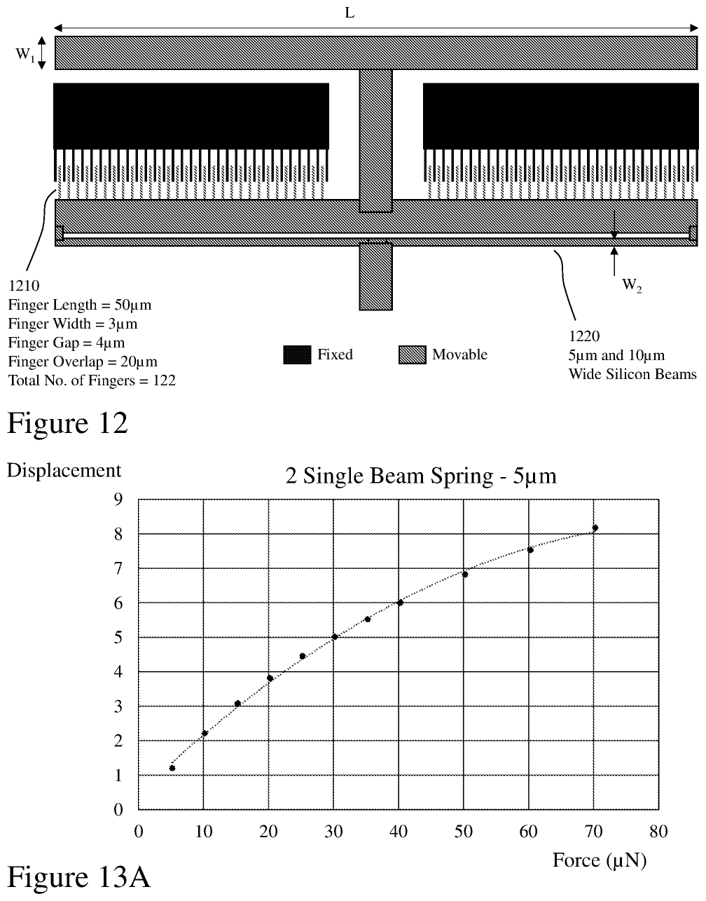

Accordingly, the phase shift produced in an optical waveguide, which for the following embodiments is described and discussed with respect to a MZI but may be a phase shift or perturbation within other photonic waveguide elements or circuits can be controlled through different configurations of MEMS actuators. Within the following embodiments of the invention the MEMS actuator 500C is described and depicted as being an electrostatic MEMS actuator. However, it would be evident that other MEMS actuators may be employed without departing from the scope of the invention. Exemplary embodiments of the invention described and depicted below in respect of FIGS. 6 to 27H combine electrostatic comb drive MEMS actuators for controlled actuation of the MEMS platform. These comb drive-based designs can be combined with linear or non-linear spring designs to obtain a variety of voltage ranges for optical tuning of the perturbation, e.g. phase shift within an MZI Exemplary schematics of linear spring and non-linear spring based designs are depicted in FIG. 2 with first and second schematics 600A and 600B, respectively. First schematic 600A for a linear spring design is described in more detail with respect to FIG. 9 and second schematic 600B for a non-linear spring design is described in more detail with respect to FIG. 12.

Electrostatic comb drive MEMS actuator (hereinafter comb drive) fabrication can be complex, and the voltage range obtained for controlled tuning of the perturbation element can be, typically, within a range of 10 V to 20 V with the displacement range typically on the order of 50 nm to 250 nm. Accordingly, embodiments of the invention have also been developed using alternative parallel plate actuation-based designs which rely upon closing of the air gap between the optical waveguide to be perturbed (i.e. the arm of the MZI upon a fixed portion of the circuit) and the perturbation element (upon a movable portion of the MEMS) completely or closing the air gap to a predetermined gap, e.g. 250 nm, using built-in mechanical stoppers. Since these parallel plate actuators work upon a pull-in phenomenon where discrete displacement occurs beyond a pull-in voltage then the inventors refer to these designs as “digital actuators”. Accordingly, at 0V the actuator is at an initial default position and above the pull-in voltage the actuator is fixed in displacement.

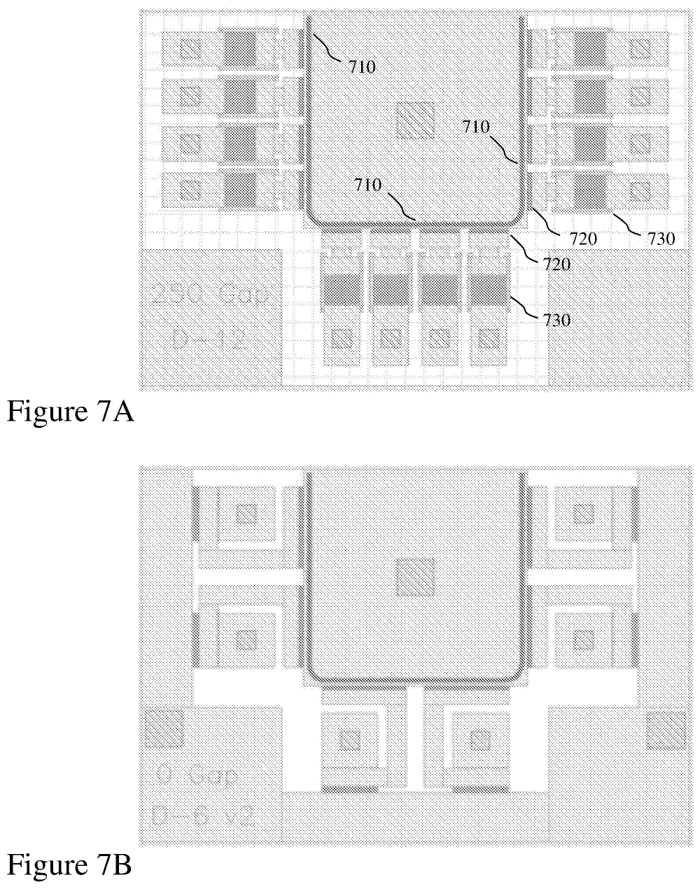

Further, as described and depicted below a long waveguide section with a single perturbation element as depicted in first and second schematics 600A and 600B respectively in FIG. 6 can be divided into multiple perturbation sections such that the multiple actuators and their associated perturbation elements provide for high resolution digital tuning. For example, using 12 digital actuators, if the complete tuning length when all digital actuators are actuated provides a π phase shift then if the actuators are all equal length a single actuator will produce a π/12 phase-shift. Exemplary designs according to embodiments of the invention with digital actuators in 250 nm gap and 0 nm gap configurations are depicted in FIGS. 7A and 7B, respectively. As depicted the 250 nm gap design in FIG. 7A comprises 12 digital actuators based upon parallel plate actuators with perturbation elements 720 and mechanical stoppers 730 coupling to the optical waveguide 710. Whilst the optical waveguide 710 is depicted in a U-shape with the actuators disposed around the three sides it would be evident that the configuration of the optical waveguide and/or positioning of the actuators can be varied without departing from the scope of the invention.

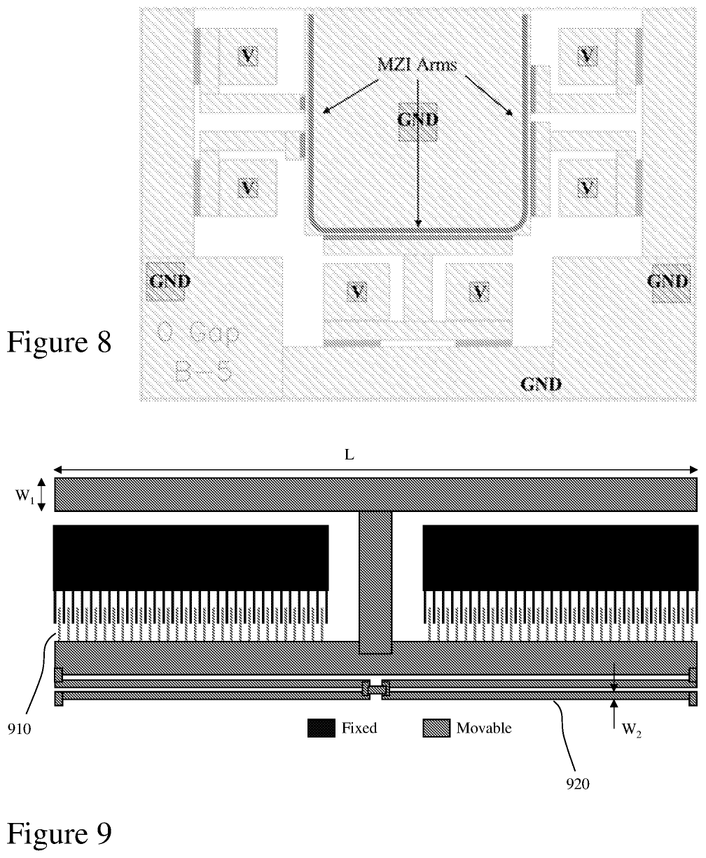

Alternatively, the digital MEMS design allows for multiple actuators of equal length or multiple actuators of different lengths such that for example one actuator may provide π/2 phase-shift, another π/3, another π/4 etc. However, it would be evident that the lengths of the multiple actuators could be design with lengths in a binary configuration where the length of a perturbation element establishes π/N where N=2ⁿ for n=0, 1, 2, 3 etc. Such a binary configuration can increase the resolution of phase shift applied to the device. For example, if a digital MEMS tunable configuration with zero gap actuators shown in FIG. 7B above can produce a minimum π/6 phase-shift with resolution of 6 then a digital binary MEMS tunable configuration such as depicted in FIG. 8 can produce a minimum optical tuning of π/32 with a resolution of 32 steps, i.e. 6 bit resolution.

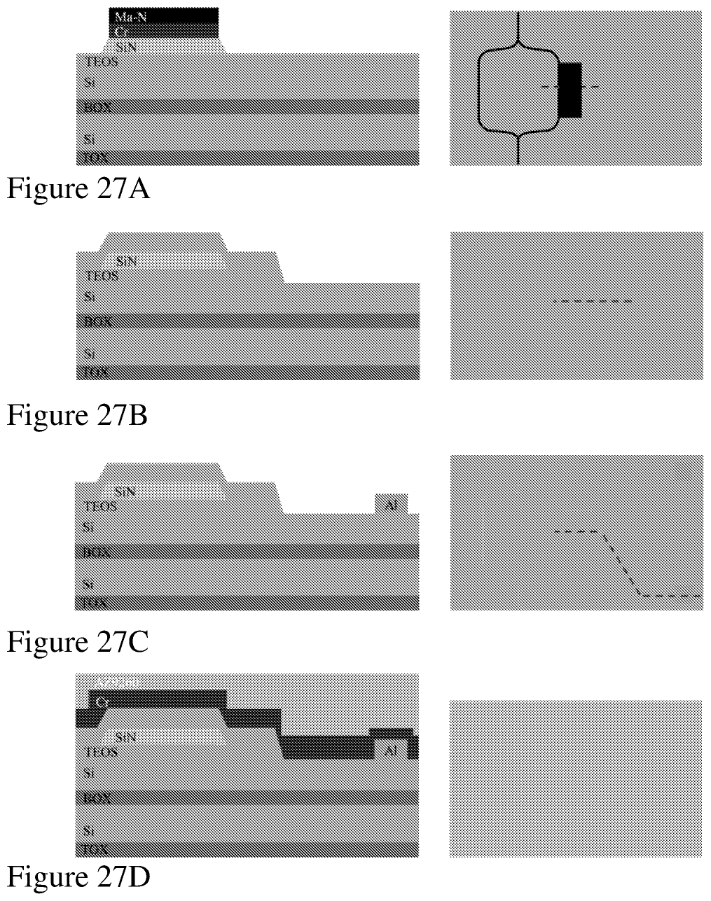

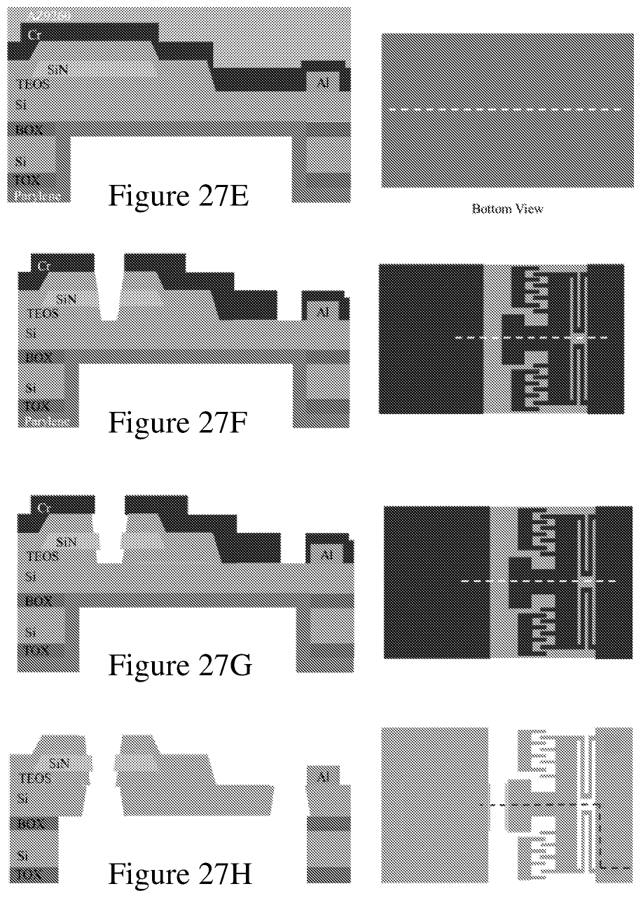

An important aspect of the fabrication of devices according to embodiments of the invention is the air gap in the perturbation region as shown in cross-sectional 500A view of FIG. 5. The etch profile of the silicon oxide and silicon nitride etching processes in commercial foundries typically cause an increase in the gap between the fixed optical waveguide and the perturbation element which cannot be compensated for using MEMS actuation. Accordingly, within the configuration depicted in FIG. 5 in cross-section 500A what is referred to as a zero gap MEMS tunable design cannot truly bring the gap between the silicon nitride cores of the fixed optical waveguide in the optical waveguide section 510 and suspended perturbation element 520 to zero because of the etch profiles. Accordingly, the inventors have established an exemplary fabrication process flow described and depicted in respect of FIGS. 26 and 27A-27H to mitigate these design challenges and to selectively etch the silicon oxide and silicon around the silicon nitride core. Accordingly, this exemplary fabrication process allows the air gap to be closed further for enhanced tuning.

2B: Analog MEMS Tunable Perturbation Elements

Initial MEMS tunable MZI designs established by the inventors according to embodiments of the invention exploited comb drive based MEMS actuators which offered continuous displacement versus voltage characteristics, i.e. what the inventors refer to as analog actuators. An initial analog MEMS based design is depicted in FIG. 9 wherein Table 1 below outlines the design parameters.

TABLE 1
Linear Spring MEMS Actuated Perturbation Element Design

| Parameter | Value | Unit |
|---|---|---|
| Length of Perturbation Element (L) | 1000 | μm |
| Width of Perturbation Element (W) | 50 | μm |
| Actuator Finger Length | 50 | μm |
| Actuator Finger Width | 3 | μm |
| Actuator Finger Gap | 4 | μm |
| Actuator Finger Overlap | 20 | μm |
| Number of Fingers | 122 | μm |
| Width of Spring Beam | 10 or 15 | μm |

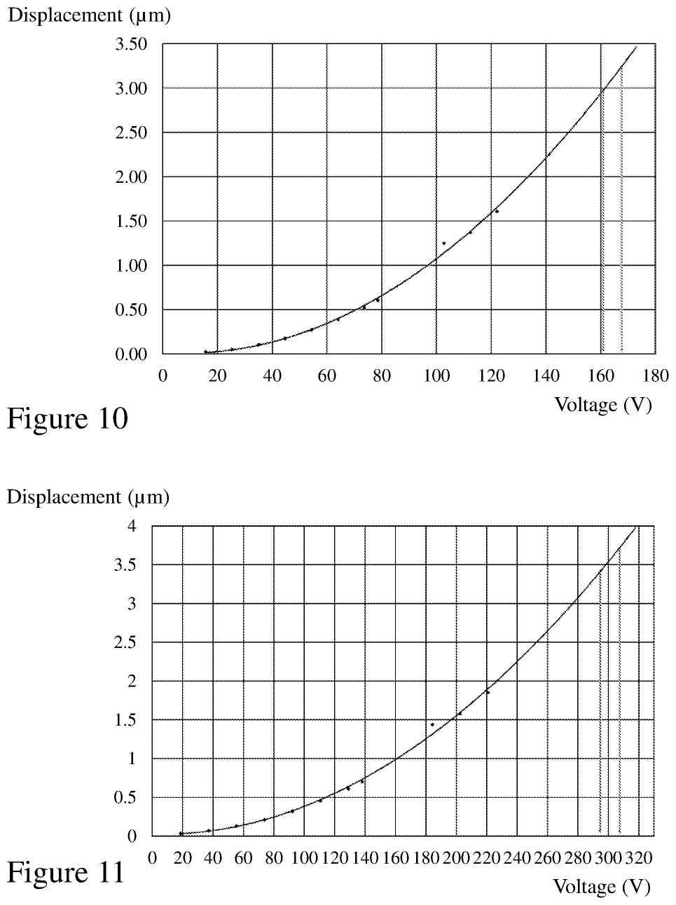

These designs were simulated using static structural analysis for a device thickness of 10 μm as employed within the commercial MEMS technology employed by the inventors. These results are depicted in FIGS. 10 and 11 for the two different spring beam widths of 10 μm and 15 μm, respectively. The inventors established that MEMS based tuning from the perturbation element occurs at an air gap of 250 nm. However, as the release process for the MEMS using the selected microfabrication technology leaves a minimum of 3 μm air gap between the movable MEMS platform and the fixed MEMS substrate and the inventors experience with other fabricated MEMS devices indicated that the gap comes out approximately 3.25 μm instead of 3 μm the MEMS actuator tuning displacement sough within simulations was 3 μm to 3.25 μm with an extended voltage range. As evident from FIGS. 10 and 11 whilst this range was obtained for the linear springs with different spring stiffness for the same comb drive design significantly different voltage performance was obtained. These results being given in Table 2.

TABLE 2
Simulated Linear Spring MEMS Actuator Performance

| Linear Serpentine Spring | | Tuning | Tuning |
|---|---|---|---|
| Beam | Spring | Displacement | Voltage |
| Width | Constant | Range | Range |
| (μm) | (N/m) | (μm) | (V) |
| 10 | 15.12 | 3.00 μm to 3.25 μm | 160 -168 (~8) |
| 15 | 49.18 | (250 nm) | 300-315 (~15) |

As expected, the lower stiffness spring system provides lower actuation voltage for a 3 μm displacement in comparison to the higher stiffness spring. However, the tuning voltage range provided by a softer spring is ˜8 V in comparison to ˜15 V for a device with stiffer spring for tuning from 3.00 μm to 3.25 μm. However, as electrostatic actuation method consumes negligible power since there is no current through the MEMS during actuation the higher voltage design is not disadvantaged per se relative to the lower voltage design.

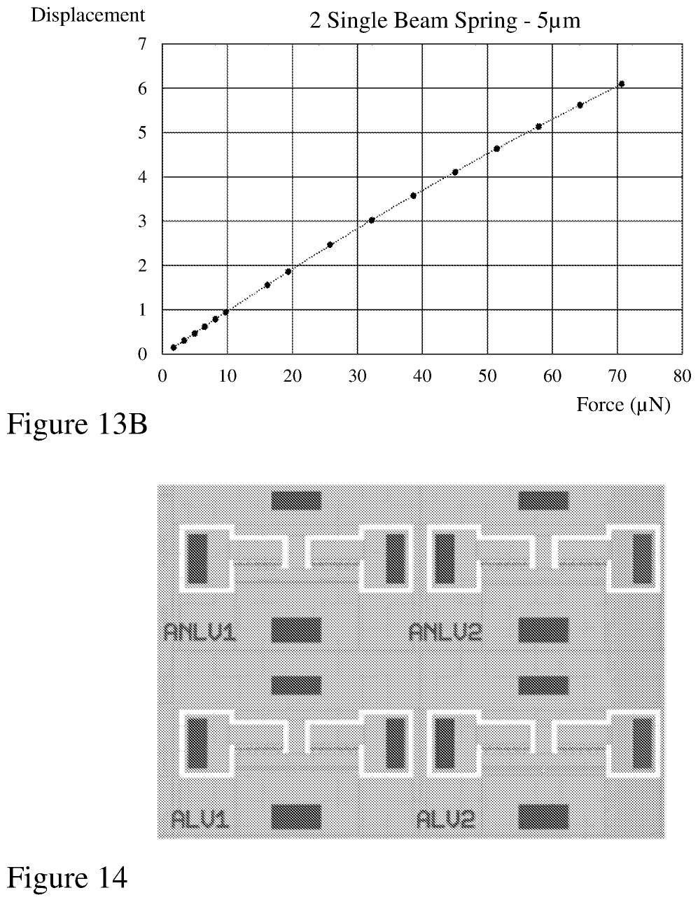

However, the inventors deemed it beneficial to further increase the tuning voltage range and accordingly, non-linear spring designs with a single silicon beam anchored only in the center were analysed as depicted in FIG. 12. The design parameters for a comparable non-linear spring of FIG. 12 to the linear spring of FIG. 9 are presented in Table 3. Again, static structural analysis was performed for these designs with 5 μm and 10 μm wide silicon beams with 10 μm think silicon as per the manufacturing process employed by the inventors. These results presented in FIGS. 13A and 13B respectively showed non-linear behavior of the spring design in displacement versus force applied. However, electrostatic simulations for these designs could not be completed at this point as the simulation was not optimized for displacement beyond approximately 2 μm as the solution would not converge due to lack of computational power.

FIG. 14 depicts an image of exemplary device layouts for test structures implemented using the commercial MEMS fabrication process selected by the inventors for the analog actuator designs presented in FIGS. 12 and Table 3.

TABLE 3
Non-Linear Spring MEMS Actuated Perturbation Element Design

| Parameter | Value | Unit |
|---|---|---|
| Length of Perturbation Element (L) | 1000 | μm |
| Width of Perturbation Element W) | 50 | μm |
| Actuator Finger Length | 50 | μm |
| Actuator Finger Width | 3 | μm |
| Actuator Finger Gap | 4 | μm |
| Actuator Finger Overlap | 20 | μm |
| Number of Fingers | 122 | μm |
| Width of Spring Beam | 5 or 10 | μm |

2C: Digital MEMS Tunable Perturbation Elements

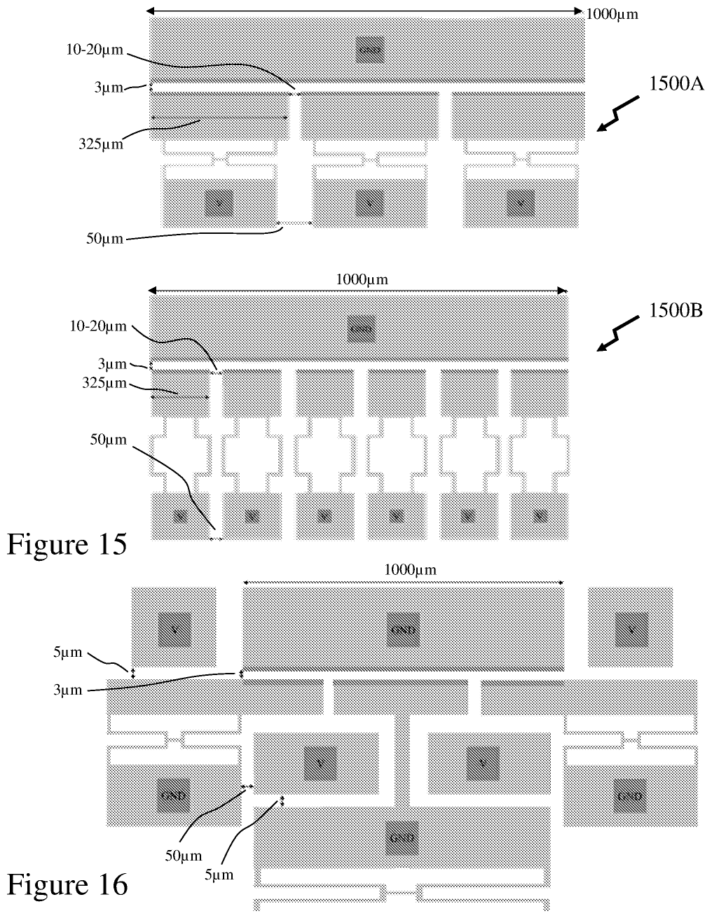

As the analog actuators based upon comb drive actuation from the preceding analysis in Section 2.B were limited in their tuning voltage range for producing the requisite range of motion of the perturbation element and accordingly, for example, induced phase shift in an MZI with low resolution the inventors established an alternative novel design methodology of tuning using parallel plate actuators. These actuators rely upon discrete ON and OFF states through electrostatic pull-in phenomena, and accordingly are referred to as digital actuators. As noted above multiple parallel plate actuators adjacent to a common optical waveguide can provide a predictable tuning in the optical waveguide, e.g. MZI, upon actuation of each actuator. Each actuator consists of a MEMS platform designed to accommodate perturbation waveguides of equal lengths as depicted in first and second schematics 1500A and 1500B in FIG. 15.

Accordingly, the first and second schematics 1500A and 1500B, hereinafter referred to as Design 1, provide the following advantages:
Parallel plate actuation based digital tuning
Substrate with optical waveguide to be perturbed is grounded;
Movable MEMS structures are at voltage;
Each actuator operates at the same voltage; and
Different spring configurations (first schematic 1500A vs second schematic 1500B for example) allow actuation voltage to be adjusted, e.g. reduced to desired level.

However, Design 1 also suffered perceived disadvantages of:
Stiction upon contact;
High power consumption with current flow; and
Potential short circuit and device damage (although this could be reduced using a high resistance in each actuation circuit driving an actuator).

A design variant of the Design 1 concept was established as depicted in FIG. 16. This, referred to as Design 2, provided the following advantages:
Parallel plate actuation based digital tuning
Substrate with optical waveguide to be perturbed is grounded;
Movable MEMS structures are also grounded;
Separate parallel plate actuator islands at voltage;
Each actuator operates at the same voltage;
Eliminates short circuit and device damage; and
Reduced power consumption with no current flow.

However, Design 2 also suffered perceived disadvantages of:
Stiction upon contact could still become an issue with large surface contact areas; and
Challenging to include more than 3 actuators within a single “cell.”

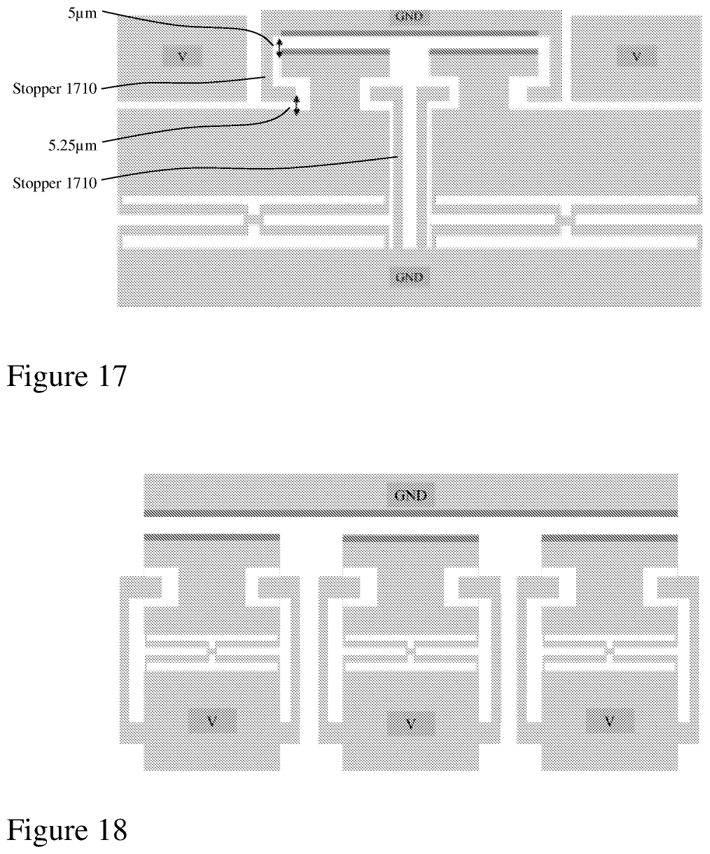

Accordingly, the inventors established a further design methodology, referred to as Design 3, where mechanical stoppers were incorporated to minimize stiction and eliminate any contact between the MEMS parts that are different potentials. Such a design being depicted in FIG. 17. Design 3, provided the following advantages:
Parallel plate actuation based digital tuning
Substrate with optical waveguide to be perturbed is grounded;
Movable MEMS structures are also grounded;
Separate parallel plate actuator islands at voltage;
Each actuator operates at the same voltage;
Dedicated set of mechanical stoppers with defined offset, e.g. 250 nm;
Eliminates stiction;
Eliminates short circuit and device damage; and
Reduced power consumption with no current flow.

However, Design 3 suffers a perceived disadvantage of:
Challenging to include more than 2 actuators within a single “cell.”

This led to further design variants being considered resulting in the design concept depicted in FIG. 18, referred to as Design 4. Design 3, provided the following advantages:
Parallel plate actuation based digital tuning
Substrate with optical waveguide to be perturbed is grounded;
Movable MEMS structures are also grounded;
Multiple actuators working at the same voltage;
Dedicated set of mechanical stoppers with defined offset, e.g. 250 nm;
Eliminates stiction;
Eliminates short circuit and device damage;
Reduced power consumption with no current flow;
Extendible in the number of actuators; and
Compact design.

The digital MEMS design concepts presented and described with respect to FIGS. 15 to 18 were further developed in order to address the specific fabrication limitations of the commercial MEMS processing technology selected for manufacturing prototype devices. These designs were categorized into two categories. The first category is where the tuning gap between the fixed substrate that holds the optical waveguide and the platform providing the perturbation element is reduced to zero air gap on each actuator. These designs require separate isolated silicon islands which acts as the fixed electrode for the parallel plate actuator design. This design provides flexibility of tuning at lower perturbation element lengths in comparison to the second design category but with a larger footprint for each actuator. The second design category is categorized by devices where the tuning gap is reduced to 250 nm using an inherent gap offset in the fabrication mask between the parallel plate actuator and an integrated mechanical stopper. This design choice may require a larger perturbation length of the perturbation element in comparison to the zero gap digital MEMS design of the first category. However, beneficially this second design category eliminates stiction between the fixed substrate part and the movable perturbation element whilst providing a compact footprint for each individual actuator.

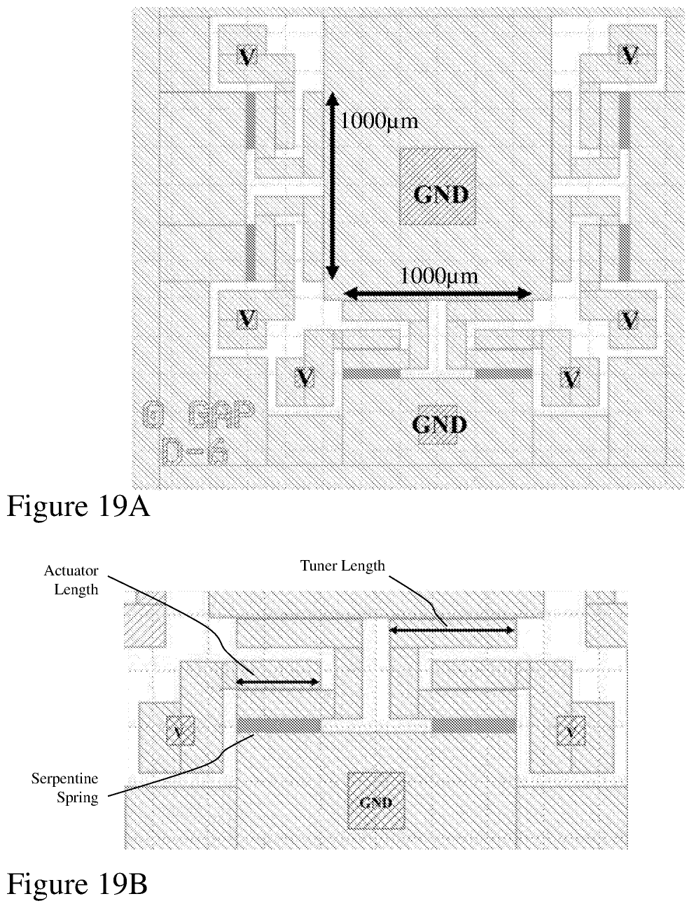

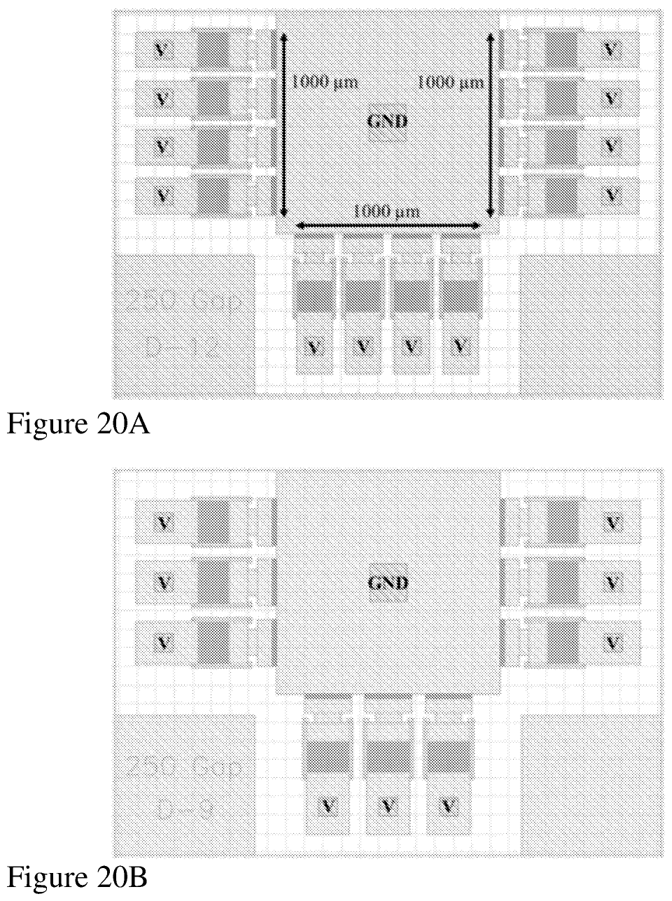

Accordingly, both of these design categories are presented in FIGS. 19A to 21B, respectively. Considering, FIGS. 19A and 19B respectively a zero gap digital MEMS actuator design is depicted as designed for the commercial MEMS fabrication process selected by the inventors. The design parameters for this design being presented in Table 4. Accordingly, if the total tuning length of 2700 μm produces a π phase shift then each zero-gap digital actuator can provide a π/6 phase shift in the design presented in FIGS. 19A and 19B through discrete actuation. Similarly, 250 nm gap digital MEMS actuators in the two actuator design iterations presented in FIGS. 20A and 20B can produce as high as π/12 phase shift through use of a single actuator. The design parameters for these designs in FIGS. 20A and 20B being presented in Tables 5 and 6, respectively.

TABLE 4
Design Parameters for Digital MEMS Actuator
Depicted in FIGS. 19A and 19B

| Parameter | Value | Unit |
|---|---|---|
| Actuator Length | 300 | μm |
| Actuator Gap | 5 | μm |
| Tuner Initial Gap | 4 | μm |
| Single Tuner Length | 450 | μm |
| Total Tuning Length | 2700 | μm |
| Number of Actuators | 6 | |
| Tuning Voltage | 110 | V |

TABLE 5
Design Parameters for Digital MEMS
Actuator Depicted in FIG. 20A

| Parameter | Value | Unit |
|---|---|---|
| Tuner Length | 210 | μm |
| Total Tuning Length | 2520 | μm |
| Number of Actuators | 12 | |
| Tuning Voltage | 150 | V |

TABLE 6
Design Parameters for Digital MEMS
Actuator Depicted in FIG. 20B

| Parameter | Value | Unit |
|---|---|---|
| Tuner Length | 250 | μm |
| Total Tuning Length | 2250 | μm |
| Number of Actuators | 9 | |
| Tuning Voltage | 100 | V |

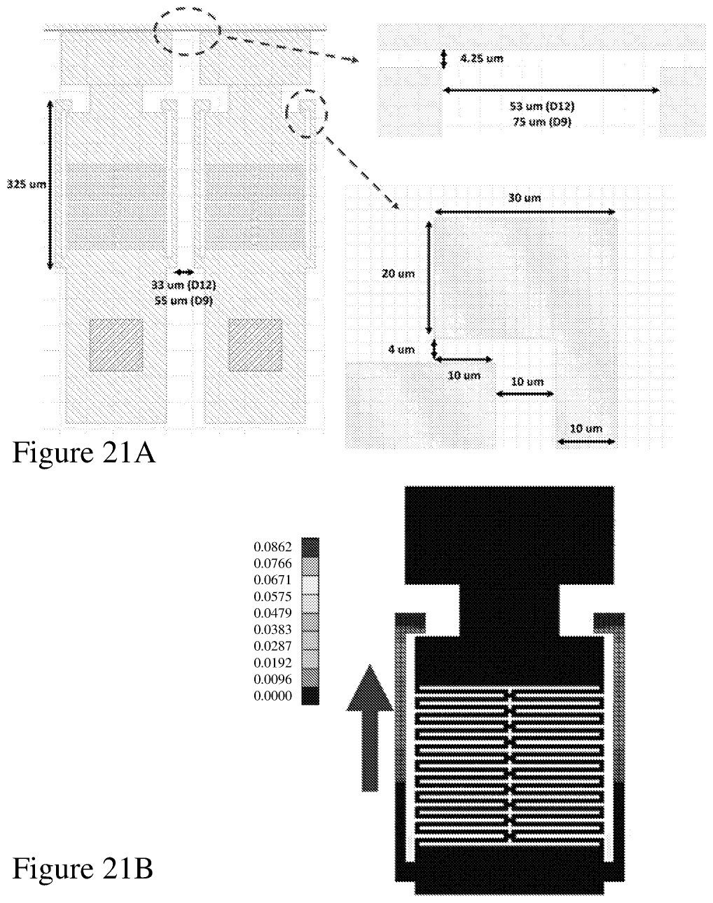

FIG. 21A depicts a pair of MEMS actuators as employed in FIGS. 20A and 20B together with detailed images of the mechanical stopper design specifications. These being summarized in Table 7. The results of electrostatic simulation for these actuators being depicted in FIG. 21B and summarized in Table 8. Since, these digital actuators operate in discrete ON and OFF states, relevant pull-in voltages (tuning voltages) are presented instead of the actuation curve for each device. FIG. 21B depicts the static structural simulation results for applied force actuation upon the stopper itself. Only 86 nm of maximum displacement was observed upon application of a 50 μN force.

TABLE 7
Design Parameters for Mechanical Stopper
Design Employed in FIGS. 20A and 20B

| Parameter | | Value | Unit |
|---|---|---|---|
| Mechanical Stopper Arm Length | | 325 | μm |
| Gap between Perturbation Element and | | 4.25 | μm |
| Optical Waveguide Element | | | |
| Gap between | 12 Actuator Design of FIG. 20A | 33 | μm |
| Mechanical | 9 Actuator Design of FIG. 20B | 55 | μm |
| Stoppers | | | |
| Gap between | 12 Actuator Design of FIG. 20A | 53 | μm |
| Perturbation | 9 Actuator Design of FIG. 20B | 75 | μm |
| Elements | | | |
| Width of Stopper “Head” | | 30 | μm |
| Depth of Stopper “Head” | | 20 | μm |
| Width of Stopper Arm | | 10 | μm |
| Gap between | Parallel to Actuator | 10 | μm |
| Stopper and | Perpendicular to Actuator | 4 | μm |
| Perturbation | | | |
| Element Structure | | | |

| | | |
|---|---|---|
| Overlap of Stopper with Perturbation | 10 | μm |
| Element Structure | | |

TABLE 8
Dimensions and Tuning Voltage Data for Digital
MEMS Actuators in FIGS. 19A-20B

| | Actuator | | Tuning Gap | | Tuning |
|---|---|---|---|---|---|
| Digital MEMS | Length | Gap | Initial | Final | Voltage |
| Actuator Type | (μm) | (μm) | (μm) | (nm) | (V) |
| Zero Gap (1) | 300 | 5.00 | 4.00 | 0 | 110 |
| 250 nm Gap (9 | 250 | 4.25 | 4.25 | 250 | 100 |
| Actuator Design) (2) | | | | | |
| 250 nm (12 Actuator | 210 | 4.25 | 4.25 | 250 | 150 |
| Design) (2) | | | | | |

Note 1:
Zero gap Digital MEMS actuator has platform and fixed substrate under optical waveguide grounded to prevent device damage upon contact. Has some stiction.
Note 2:
Mechanical stopper designed at 4 μm gap for 250 nm offset upon actuation. Minimum stiction.

2D: Binary MEMS Tunable Perturbation Elements

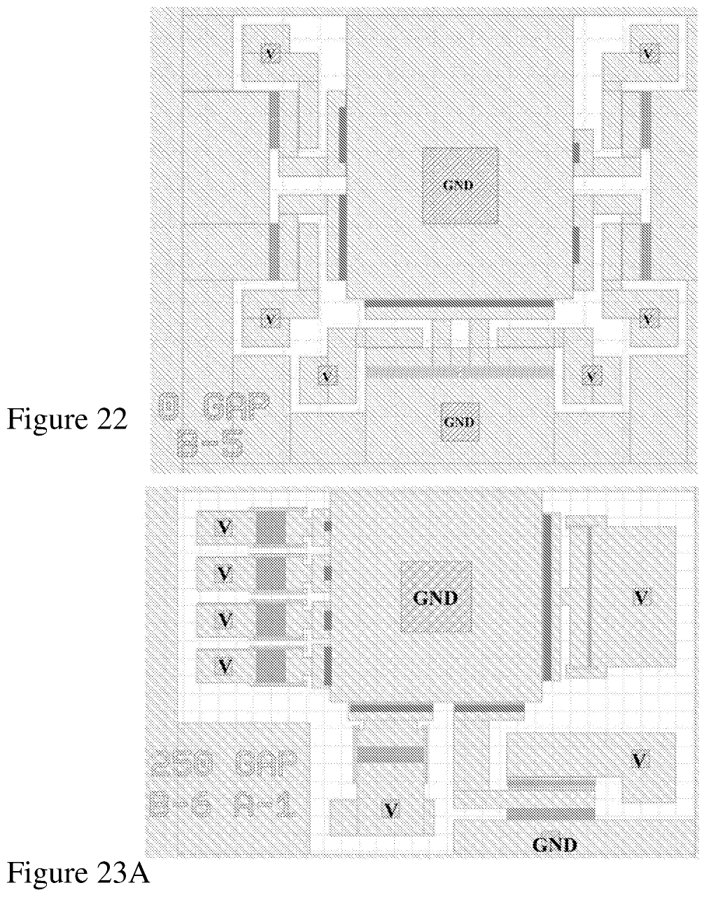

The digital MEMS actuator designs discussed in Section 2C provide actuators supporting high resolution tuning through discrete actuation of each actuator. However, to further enhance the resolution of the tuning (i.e. phase shift) obtained upon use of these digital actuators, the inventors as noted above propose exploiting different perturbation element lengths on different platforms. Further, such lengths could be scaled by a multiple of two between elements thereby enabling a binary combination of the multiple actuators. Such a binary combination of discrete tuning elements can increase the degree of control over the induced perturbations, e.g. phase shift, multifold relative to a number of equal length perturbation elements. Further, as discussed in Section 2C MEMS actuators designed for embodiments of the invention were designed for fabrication upon the commercial MEMS fabrication process selected by the inventors and were also categorized on the basis of having either a zero tuning gap or a 250 nm tuning gap. Referring to FIG. 22 there is depicted a zero gap binary MEMS actuator for the commercial MEMS fabrication process selected by the inventors with 5 actuators. The actuator designs remain largely similar to the zero gap actuator designs presented in Section 2C. Zero gap tunable MEMS designs use the same actuator lengths for 4 of the actuators where only the perturbation element size is reduced in case of small binary lengths to minimize stiction upon actuation. The fifth actuator, at the bottom of the structure in FIG. 22 was designed to accommodate a 1000 μm long perturbation element. Through modifications to the number of serpentine spring beams and width of the silicon beam, this actuator was also designed to operate at the same tuning voltage as the other 4 actuators. The design parameters for this zero gap binary MEMS design being presented in Table 9.

TABLE 9
Design Parameters for Zero Gap Binary
MEMS Actuator Depicted in FIG. 22

| Parameter | | Value | Unit |
|---|---|---|---|
| Actuator Gap | | 4.25 | μm |
| Stopper Gap | | 4.00 | μm |
| Number of Actuators | | 5 | |
| Tuner Length | #1 | 1000 | μm |
| | #2 | 500 | μm |
| | #3 | 250 | μm |
| | #4 | 125 | μm |
| | #5 | 62.5 | μm |

| | | |
|---|---|---|
| Total Tuning Length | 1937.5 | μm |
| Tuning Voltage | 110 | V |

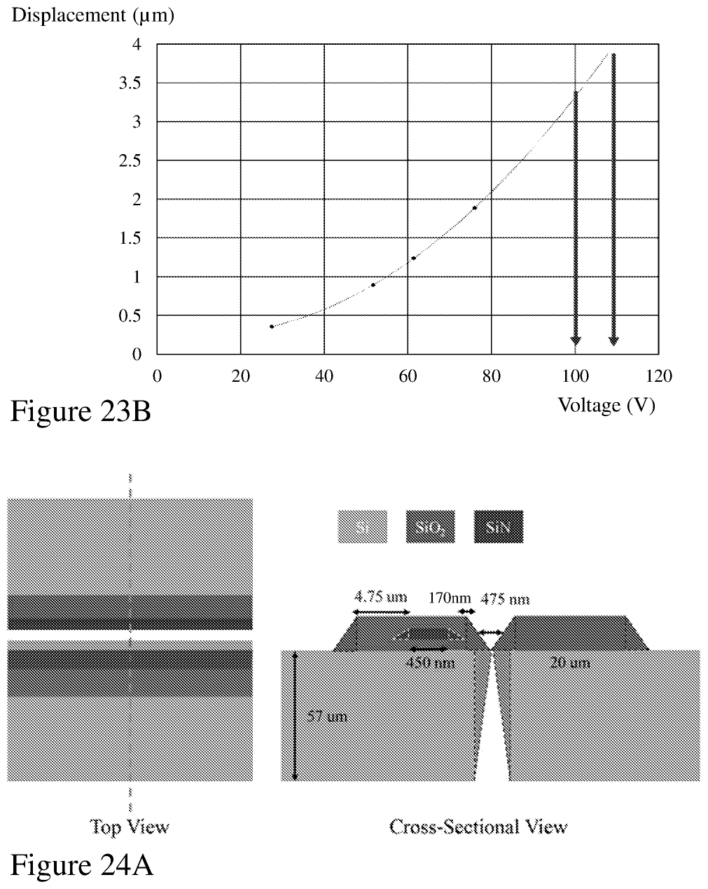

Similar adjustments were made to the 250 nm gap digital MEMS actuator design described above in Section 2C to yield the 250 nm gap binary MEMS actuator for the commercial MEMS fabrication process selected by the inventors. The binary configuration in this instance as depicted in FIG. 23A employs 6 digital actuators based upon parallel plate actuation as discussed previously. In this instance, the length of the actuator platform was not reduced below 210 μm in order to maintain a low actuation voltage. The platforms and the actuators were designed to accommodate binary lengths of perturbation elements with a maximum length of 960 μm. With the increase in platform size, the actuator size also increases which lowers the tuning voltage for the large binary length actuators. The design parameters for this 250 nm gap binary MEMS design being presented in Table 10.

TABLE 10
Design Parameters for 250 nm Gap Binary
MEMS Actuator Depicted in FIG. 23A

| Parameter | | Value | Unit |
|---|---|---|---|
| Actuator Length | | 300 | μm |
| Actuator Gap | | 5 | μm |
| Number of Tuning Actuators | | 6 | |
| Binary Combinations | | 64 | |
| | Actuator | Perturbation | Tuning |
| | Length | Element Length | Voltage |
| Actuator | (μm) | (μm) | (V) |
| 1 | 960 | 960 | 40 |
| 2 | 480 | 480 | 70 |
| 3 | 250 | 240 | 100 |
| 4 | 210 | 120 | 150 |
| 5 | 210 | 60 | 150 |
| 6 | 210 | 30 | 150 |

It would evident that the design depicted in FIG. 23A actually comprises 7 actuators. This is because an analog actuator was also added to the design in the available space where the analog actuator can help in enhanced tuning in each of the binary combinations; if required. Simulation results for this analog actuator are presented in FIG. 23B.

2E: Optical Analysis

The inventors have established several design approaches for the tuning of an optical waveguide using perturbation elements exploiting digital actuators and/or analog actuators individually or in combination. Within the following overview several design approaches are presented with respect to the tuning of an oxide-nitride-oxide (ONO) waveguide structure with a silicon oxide lower cladding, a silicon nitride waveguide core and an upper silicon oxide cladding, i.e. a SiO₂—Si₃N₄—SiO₂ waveguide structure. However, it would be evident to one of skill in the art that other design methodologies may be employed without departing from the scope of the invention either for an ONO waveguide structure or for other waveguide structures. For example, materials with higher refractive indices than the optical waveguides may be employed to increase the perturbation strength per unit length or allow larger gaps to be employed, materials with lower refractive indices than the optical waveguides may be employed to decrease the perturbation strength, materials with complex refractive indices may be employed, etc.

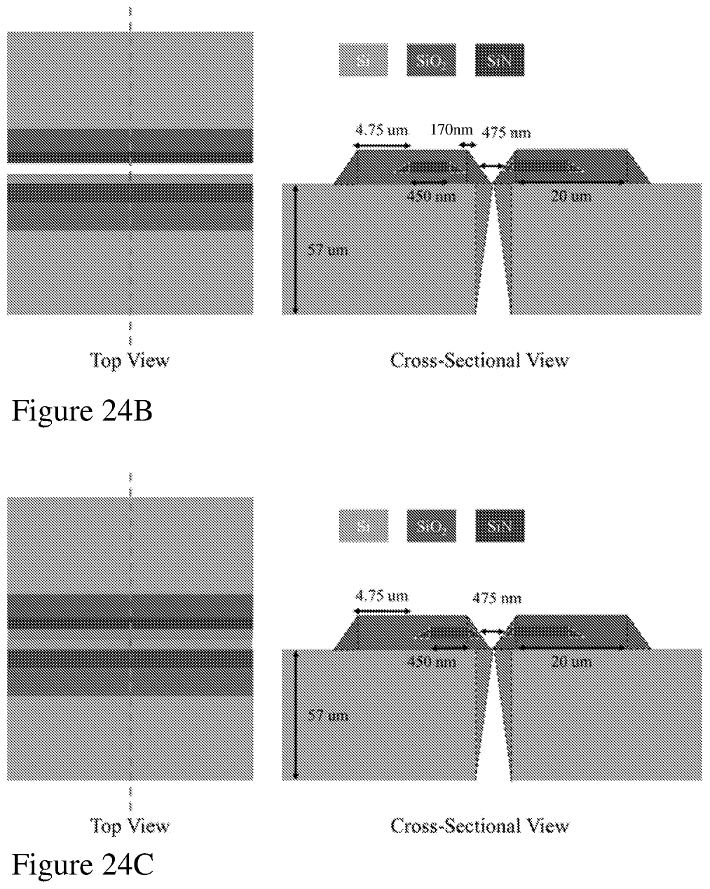

Accordingly, considering an ONO waveguide structure without additional materials being added to the fabrication process then in a first option the optical waveguide is formed within the ONO stack and the perturbation element may be similarly another element formed within the ONO stack upon the moving Si MEMS platform of the MEMS actuator. Alternatively, the perturbation element may be simply an oxide layer on top of the Si MEMS platform such as depicted in FIG. 4. In either instance the etch profile of the optical waveguide and the perturbation element in the tuning region plays a significant role in defining the MEMS design(s) and the microfabrication process flow. Ideally, the etch profile in the tuning gap would be a 90 degree etch for all of the layers involved. However, through the commercial MEMS microfabrication process employed by the inventors for optical device integration with MEMS devices the processing yields an 86° etch profile for the oxide and ONO layer etches. The etch profile for the silicon nitride core is 80°, whilst the etch profile for the silicon MEMS etch is an inverted 91° angle. Accordingly, these microfabrication aspects result in different perturbation scenarios which are depicted in FIGS. 24A to 24C, respectively.

Accordingly, referring to FIG. 24A there are depicted plan and cross-sectional views of an ONO optical waveguide with SiO2 perturbation element at zero gap where there is oxide on the side of the ONO optical waveguide disposed towards the perturbation element.

FIG. 24B depicts plan and cross-sectional views of an ONO optical waveguide with an ONO perturbation element at zero gap where there is oxide on the side of the ONO optical waveguide disposed towards the perturbation element but no (or minimal) oxide on the side of the perturbation waveguide disposed towards the ONO optical waveguide.

FIG. 24C depicts plan and cross-sectional views of an ONO optical waveguide with an ONO perturbation element at zero gap where there is no (or minimal) oxide on the side of the ONO optical waveguide disposed towards the perturbation element but no (or minimal) oxide on the side of the perturbation waveguide disposed towards the ONO optical waveguide.

TABLE 11
Optical Simulation Results for ONO Waveguides
with Various Perturbation Elements

| | Phase Shift | |
|---|---|---|
| Design | L = 1000 μm | L = 1300 μm |
| FIG. 24A | 0.25 π | 0.33 π |
| FIG. 24B | 0.36 π | 0.47 π |
| FIG. 24c | 1.08 π | 1.4 π |

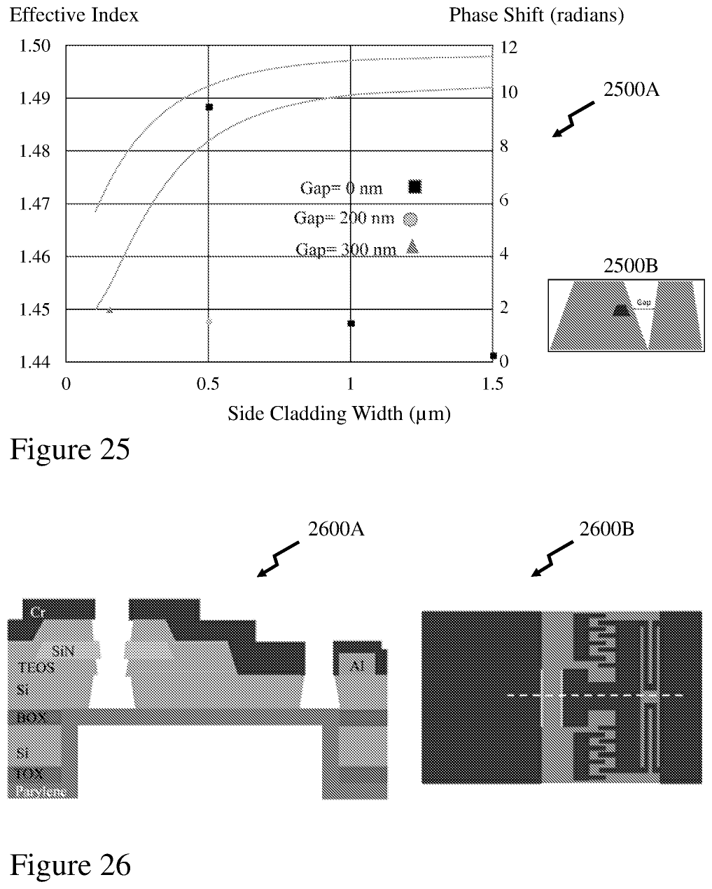

The structures depicted in FIGS. 24A to 24C were modelled for a silicon nitride waveguide width of 435 nm resulting in the phase shifts outlined in Table 11. These simulations being performed for optical signals at 1550 nm wavelength which is widely used in the telecommunication industry. The etch profile for the silicon nitride causes the lower width of the waveguide core to be 450 nm for a 435 nm designed core width as depicted in FIGS. 24A to 24C, respectively. Also evident in FIGS. 24A and 24B, as visible in the etch profiles presented, is that even perfect alignment between the silicon oxide and silicon nitride etch steps leads to a side cladding of approximately 170 nm. Accordingly, these etch slopes lead to a minimum gap 475 nm between the ONO waveguide and perturbation element. Such perfect alignment for the oxide side cladding with the waveguide core is nearly impossible and accordingly variations in this would be expected from the inherent manufacturing tolerances of the fabrication process employed. Accordingly, further optical simulations were performed to assess the alignment tolerance provided for an ONO waveguide with different side cladding dimensions when the perturbation element is an oxide only design such as depicted in FIG. 24A. These simulation results are presented in graph 2500A FIG. 25 for the geometry depicted in insert 2500B. The waveguide width chosen for these simulations was 300 nm for a silicon nitride thickness of 435 nm for a length of 1000 μm at three different gaps for the perturbation element, these being 0 nm, 200 nm, and 300 nm. From these simulations at a gap of 300 nm between the ONO waveguide and the perturbation element a side cladding of less than 250 nm can lead to a a phase shift over the length of 1,000 μm. If the gap can be reduced to 0 nm, a phase shift close to a can be obtained with a side cladding of 1 μm. Where a longer perturbation length can be employed then a it phase shift can be obtained for a larger gap between the ONO waveguide arm and the perturbation element. However, the typical objective for photonic circuits is smallest footprint to either increase the die per wafer count to reduce cost per die or allow increased integration density of implemented circuits. Accordingly, the inventors established a microfabrication process flow compatible with the commercial manufacturing process selected by the inventors to overcome this fabrication limitation allowing implemented circuits according to embodiments of the invention to be implemented with near zero gap between the ONO waveguide with ONO etch facet and ONO based perturbation element such as depicted in FIG. 24C.

2F: Microfabrication Sequence for Near Zero Gap Implementation of ONO Waveguide—ONO Perturbation Element

As discussed above the integration of MEMS actuators with silicon nitride based optical waveguides for perturbation through gap closing of a perturbation element presents fabrication challenges. The commercial process flow can provide an ONO stack or oxide with an 86° etch profile. The silicon nitride etch angle remains at 80° and the etch angle for silicon is inverted 91°. As noted these fabrication limitations can lead to a minimum gap of 475 nm between the ONO waveguide core and the perturbation element. In order to compensate for these fabrication limitations, the inventors established a MEMS tunable perturbation geometry with the ONO facet for the optical waveguide with another ONO facet for the perturbation element such as depicted in FIG. 24C which as outlined in Table 11 can achieve significantly higher phase shift per unit length when compared to the designs of FIGS. 24A and 24B respectively.

The ONO etch to get this initial tuning gap can be achieved through photolithography eliminating alignment issues between the silicon oxide layer and the silicon nitride layer. Accordingly, the manufacturing sequence established by the inventors which is compatible with the commercial MEMS fabrication processes and tolerances exploits a highly selective vapor HF etch to selectively etch excess silicon oxide around the silicon nitride core in the tuning gap region. This helps reduce the tuning gap further enabling larger phase shifts per unit length. In order to implement this a chromium hard mask is used for this step. A cross-sectional view 2600A of the tuning gap region for a design according to embodiments of the invention with slightly overhanging silicon nitride during this step is shown in FIG. 26 prior to removal of a parylene layer to release the MEMS element. FIG. 26 also depicts a top view 2600B of the MEMS tunable structure during the selective silicon oxide removal step using a chromium hard mask. As evident this step results in slight overhangs of silicon nitride for the ONO waveguide and ONO perturbation element.

A detailed process flow proposed for microfabrication of the MEMS tunable ONO waveguides with silicon nitride overhangs in the perturbation region is presented in FIGS. 27A to 27H, respectively. The following provides a brief description each of the key steps involved in each of these Figures.

FIG. 27A: The bottom silicon oxide cladding deposition over an SOI wafer is followed by silicon nitride layer deposition and patterning using a chromium hard mask (Mask 1) with e-beam or UV stepper photolithography.

FIG. 27B: Deposition and patterning of the top silicon oxide cladding is performed using UV lithography (Mask 2).

FIG. 27C: Deposition and patterning of aluminum based metal bonding pads for actuation and wire bonding is implemented using a further mask (Mask 3).

FIG. 27D: A thick photoresist deposition is performed after a chromium deposition step to protect the frontside features before backside processing.

FIG. 27E: The backside cavity is opened through buried oxide etching using UV lithography and wet etching processes (Mask 4) followed by parylene deposition for MEMS layer protection before release.

FIG. 27F: The chromium hard mask is patterned using UV lithography (Mask 5) followed by etching of the ONO stack in the tuning/perturbation gap region.

FIG. 27G: Selective vapor HF etch removes silicon oxide from the exposed ONO facets resulting in silicon nitride overhangs on the ONO waveguide and ONO perturbation element.

FIG. 27H: Deep reactive ion etching (DRIE) of the silicon device layer of the SOI defines the MEMS fabrication followed by etching of the parylene layer to release the optical MEMS perturbation element.

2G: Summary

Accordingly, within Section 2 novel MEMS based tuning elements for inducing perturbations within optical waveguides have been described and depicted with respect to FIGS. 5 to 27H, respectively. The design methodology outlined provides for:
Simple one-dimensional (1-D) mechanical design for planar MEMS based tuning;
Controlled tuning using both analog actuators and digital actuators;
Analog tuning through use of comb drive with linear serpentine springs;
Analog tuning through use of comb drive non-linear clamped beams springs for extended tuning voltage range;
Digital tuning using multiple parallel plate actuators with the same operational voltage;
Binary digital configuration for the perturbation elements for high resolution tuning;
Stiction elimination mechanism through unique mechanical stopper design built within the actuator to prevent shorting upon actuation;
Simple device operation through elimination of complex comb drive structures in digital actuator designs;
Ease of fabrication due to simple parallel plate actuators for digital tuner devices;
Cost effective fabrication using UV stepper photolithography processing;
Integration of perturbation elements with ONO waveguides that are optimal for telecommunication applications compared to silicon waveguides due to efficient transmission around 1550 nm wavelength; and
Low power, low temperature, and fast tuning in comparison to prior art thermal tuning methods.

Accordingly, embodiments of the invention provide fast and low power MEMS based solutions for tuning optical components with controlled phase shift or other perturbations.

Section 3: Serially Coupled Ring Resonator Assisted Mach-Zehnder Interferometer Tunable Bandpass Filters

The ever-increasing demand for bandwidth in data communication and telecommunication systems has resulted in the development of dense wavelength division multiplexing (DWDM) at 200 GHz, 100 GHz and 50 GHz channel spacings to support networks with 40, 80 and 160 channels of 10 Gb/s (OC-192) data on the C-band (1529 nm-1568 nm) and L-bands (1569 nm-1610 nm). However, such networks require planning and structured deployment. Accordingly, there is increasing interest in gridless networks, also known as elastic optical networks (EONs), where the channel spacing and bandwidth can be adjusted dynamically. Accordingly, EONs would allow operators to dynamically maximize the available bandwidth and limit spectrum wastage. However, in front of each optical detector there must be an optical filter to isolate the channel that optical detector receives. With DWDM networks such filters were typically static in wavelength and fixed in optical bandwidth (e.g. designed for a specific 200 GHz, 100 GHz or 50 GHz channel) requiring planned deployment, inventory management etc. In some instances, tunable optical filters are deployed allowing selection of a channel from a number of channels but again the optical bandwidth was fixed, and the tuning range/tuning speed limited in many technologies employed.

Accordingly, to be useful in EONs, the optical filters should be tunable both in optical bandwidth and center frequency. For example, dynamically allocating 40 Gb/s to specific nodes rather than 10 Gb/s requires a different optical bandwidth even if the same centre wavelength is used. Additionally, these filters should have low insertion loss, a flat-top response, a box-like passband, high extinction ratio and high side-band rejection.

Within the prior art multiple design to implement optical filters with an optimized passband response have been proposed and the evolution of optical communications to EONs has seen increasing interest in reconfigurable bandpass filters (BPF) with tunable bandwidth and wavelength. Amongst, these designs ring resonators are the most commonly employed filtering components in these filters as they are easy to fabricate and have a small footprint. One approach to implementing a BPF is the Ring Assisted Mach-Zehnder interferometer (RA-MZI) wherein one or more ring resonators (RRs) are embedded in one or both of arms of a Mach-Zehnder interferometer (MZI) as this configuration offers a more boxlike passband response when compared to simply cascading RRs. However, as the number of RR elements increases in these RA-MZI filters, the tuning mechanism to achieve the optimum filter shape for the filter becomes more and more complex.

A simpler tuning requirement is offered by a prior art filter architecture using an unbalanced MZI and two cascaded RRs. Accordingly, the inventors have established based upon this architecture novel bandpass filters with desired performance parameters exploiting different coupling configurations between the RRs and MZI Amongst these, a second order filter with two RRs in series and in parallel to the MZI was analyze yielding to the inventor's knowledge the first implementation of a BPF using a serially coupled Ring Resonators and MZI (SR-MZI) configuration in which two RRs are connected in series to the MZI. Moreover, the inventors observed that the response of this SR-MZI filter offers several advantages compared to previous configurations; specially in terms of the shape of the bandpass response and the degrees of freedom to optimize the various performance parameters. Further, the inventors have established a novel MEMS based tuning mechanism for such an SR-MZI allowing the tuning to be performed with low power and without thermal crosstalk considerations with other elements of a photonic circuit within which the tunable BPF is integrated.

In common with the polarisation rotator and phase shifter devices described and depicted in respect of Sections 1 and 2 the inventors have analysed and fabricated novel tunable BPFs based upon a commercial CMOS compatible MEMS microfabrication process and ONO (SiO₂—Si₃N₄—SiO₂) waveguide structures. Accordingly, using MEMS elements the inventors have established tunability of the filter bandwidth and filter shape by varying the coupling between the RRs themselves and the RR(s) with the MZI.

3A: Device Design

3A1: Analytical Modelling of Various RA-MZI Configurations

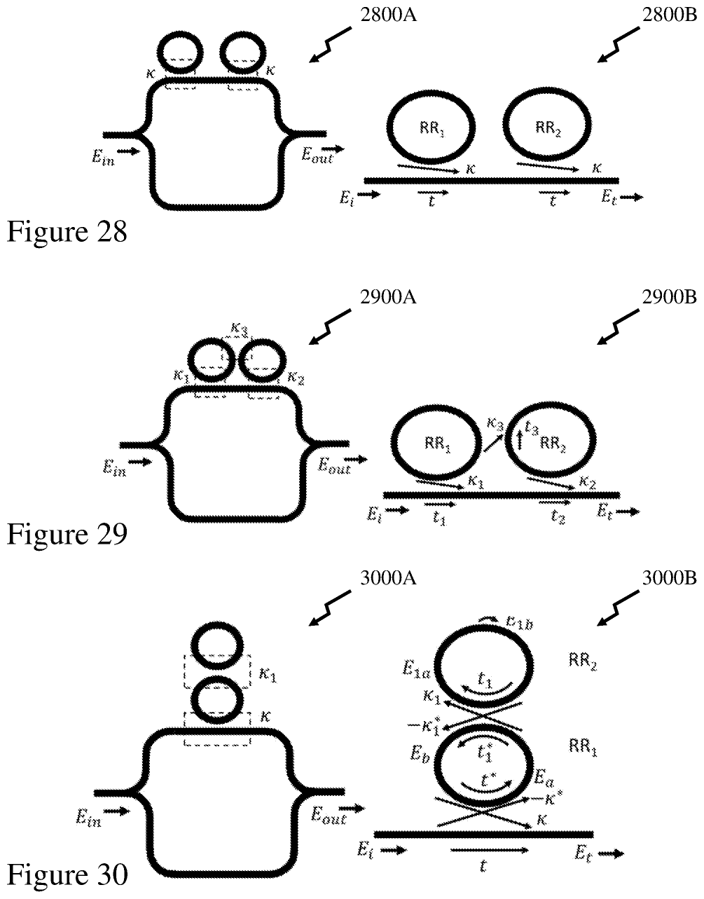

Referring to first schematic 2800A in FIG. 28 there is depicted a first RA-MZI configuration (hereinafter referred to as Design 1) which can be used to obtain a bandpass response with two ring resonators. Each RR is coupled to the shorter arm of the MZI in parallel and there is no coupling between the RRs. This configuration being known from the prior art.

The field transmission and coupling coefficients between the MZI and RRs are represented by t and K, respectively. The loss in the RRs is represented by α and the phase change is θ=−iβL, where, L is the circumference of the RRs and β is propagation constant of the ring waveguide. The complex electric field, Eₜ, at the output of the cascaded rings second schematic 2800B in FIG. 28 can simply be written in terms of the product of transfer function of the two all-pass filters as Equation (1). Equation (1) can be substituted in Equation (2) to obtain the output field, E_{OUT}, of the RA-MZI shown in first schematic 2800A in FIG. 28 where, θ_{MZI}=−iβL_{MZI} and L_{MZI} is the length difference between the arms of the MZI E_{IN} is the input electric field which can be assumed to be unity in the model.

Eₜ=Eᵢ×((t−a exp(iθ))²/(1−αt*exp(iθ))²) (1)

E_{OUT}=0.5E_{IN}×[exp(iθ_{MZI})+(Eₜ/Eᵢ)] (2)

Referring to FIG. 29 there are depicted first and second schematics 2900A and 2900B of an RA-MZI with parallel coupling between the RRs and MZI, however, coupling is now introduced also between the two RRs. This being referred to by the inventors subsequently as Design 2. The coupling between RRs being shown in first schematic 2900A whilst second schematic 2900B depicts a schematic of the MZI bus waveguide with the two coupled RRs used in this filter. The analytical response of this device can be obtained using a scattering matrix formulation, or the cumbersome but intuitive method of equating fields. The field coupling coefficients between the ring resonators and the MZI are represented by K₁ and K₂ whilst that between the ring resonators is represented by K₃. The phase-shifts in the two rings are represented by θ₁ and θ₂, respectively. The complex electric field, Eₜ, at the output of the cascaded RRs of second schematic 2900B is given by Equation (3) where the denominator A is given by Equation (4) and the terms t₁₃, t₁₃, and t₁₃ by Equations (5) to (7) respectively.

Eₜ=Eᵢ×(A/(1−t₁₃−t₂₃+t₁₂)²) (3)

A=(K₂²\sqrt{(1−K₁²)}exp(i(θ₁+θ₂)−K₂²\sqrt{(1−K₃²)}exp(iθ₂)))×(\sqrt{(1−K₁²)}−exp(iθ₂)\sqrt{(1−K₁²)(1−K₂²)(1−K₃²)}−exp(iθ₁)\sqrt{(1−K₃²)}+exp(i(θ₁+θ₂))\sqrt{(1−K₂²)})−K₁²K₂²K₃² exp(i(θ₁+θ₂))+(K₁²(1−K₂²)exp(i(θ₁+θ₂)−K₁²\sqrt{(1−K₂²)(1−K₃²)}exp(iθ₁))(1−t₁₃−t₂₃+t₁₂))+\sqrt{(1−K₁²)(1−K₂²)}(1−t₁₃−t₂₃+t₁₂)² (4)

t₁₃=\sqrt{(1−K₁²)(1−K₃²)}exp(iθ₁) (5)

t₂₃=\sqrt{(1−K₂²)(1−K₃²)}exp(iθ₂) (6)

t₁₂=\sqrt{(1−K₁²)(1−K₂²)}exp(i(θ₁+θ₂)) (7)

Equation (3) can be substituted in Equation (2) to get the expression for the electric field, Eₜ, at the output of the RA-MZI filter in first schematic 2900A in FIG. 29. The response of this filter is reflective in nature due to coupling between the rings and therefore is not suitable as a bandpass filter as shown in the next section.

Referring to FIG. 30 there are depicted first and second schematics 3000A and 3000B of the SR-MZI according to embodiments of the invention wherein the two RRs are coupled to the MZI ins series as depicted in first schematic 3000A. This being referred to by the inventors subsequently as Design 3. This configuration has not been investigated as a bandpass filter in the prior art. Second schematic 3000B in FIG. 30 shows the MZI bus waveguide with the serially coupled RRs used in this filter. The various electric field components, field transmission and coupling coefficients are also shown. The variables α, α₁, θ and θ₁ represent the losses and phase-shift in the rings RR1 and RR2, respectively. The interactions of these field components can be represented by Equations (8) to (12) respectively.

Eₐ=−K*Eᵢ+t*α exp(iθ/2)E_{b} (8)

E_{b}=t₁*α exp(iθ/2)Eₐ−K₁*α₁ exp(iθ₁/2)E_{1b} (9)

E₁ₐ=K₁α exp(iθ/2)Eₐ−t₁α₁ exp(iθ₁/2)E_{1b} (10)

E_{1b}=α₁ exp(iθ₁/2)E₁ₐ (11)

Eₜ=tEᵢ+Kα exp(iθ/2)E_{b} (12)

Accordingly, the electric field, Eₜ, at the output of the serially coupled RRs in second schematic 3000B in FIG. 30 can be calculated using Equations (8) to (12) in conjunction with Equation (13)

$${E}_{t} = {E}_{i} \times \frac{( {α}^{2} {α}_{1}^{2} exp ( i ( {θ}_{1} + {θ}_{2} ) ) - {t}_{1} ( {α}^{2} exp ( i θ ) + t {α}_{1}^{2} exp ( i {θ}_{1} ) ) + t )}{( t {α}^{2} {α}_{1}^{2} exp ( i ( θ + {θ}_{1} ) ) - {t}_{1} ( t {α}^{2} exp ( i θ ) + {α}_{1}^{2} exp ( i {θ}_{1} ) ) + 1 )} \qquad ( 13 )$$

The expression for Eₜ, in Equation (13) can be substituted into Equation (2) to obtain the output of the filter depicted in first schematic 3000A in FIG. 30.

3A.2 Filter Responses

In the various second order RA-MZI configurations discussed above, and depicted in FIGS. 28 to 30, the RRs are coupled to the shorter arm of the MZI and the length of the RRs is equal to the difference in length between the two arms of the MZI Within the following analysis this length has been optimized such that the free spectral range (FSR) of the ring resonators and MZI is equal to 200 GHz (i.e. 1.6 nm at a wavelength of 1550 nm). The FSR was chosen only to demonstrate the proof of concept and it can be increased by reducing the size of the rings, or by utilizing the Vernier effect in the coupled rings. Since the TE and TM polarizations have slightly different modal properties for the ONO waveguides analysed the inventors optimized all of the designs for the TE polarization at the telecommunication wavelength of 1550 nm. However, it would be evident that the design principles outlined below with respect to novel SR-MZI designs according to embodiments of the invention may be applied to other waveguide technologies without departing from the scope of the invention.

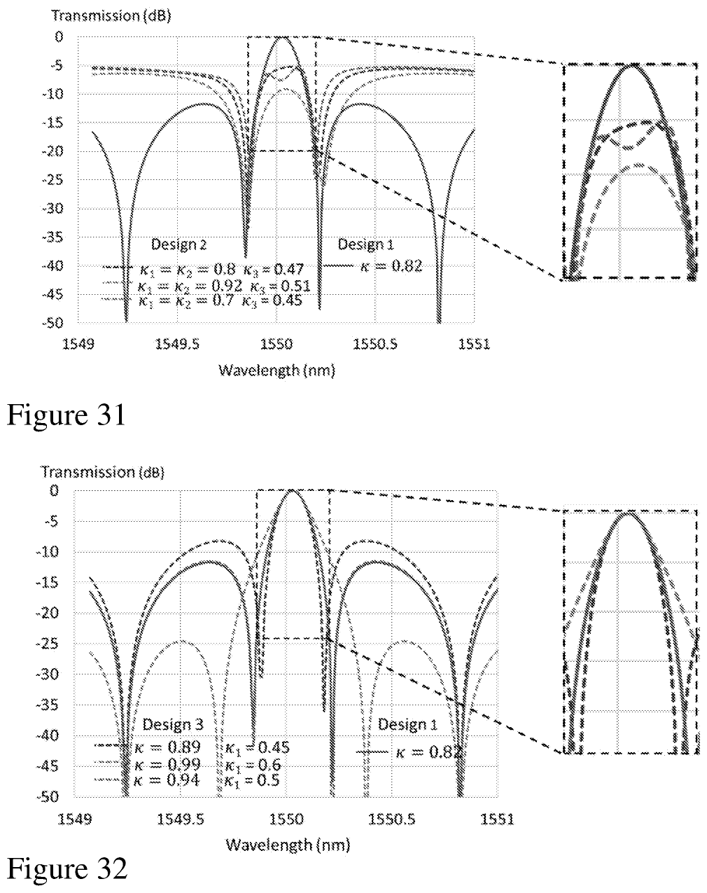

To compare the performance of each of the architectures of Designs 1 through 3, the coupling coefficients were optimized to achieve a 3-dB bandwidth of 0.14 nm. For example, the coupling coefficient K in Design 1 needs to be 0.82 to provide the desired 3-dB bandwidth. FIG. 31 shows the spectral response of Design 1 and Design 2 where the coupling coefficients of Design 2 are optimized to achieve the same bandwidth as Design 1. For K₁=K₂=0.8 and K₃=0.47 a flat passband is obtained. However, the passband has a high insertion loss and the sidebands are at the same level as the passband. As shown in FIG. 31, tuning of the coupling coefficients K₁, K₂ and K₃ around these values further increases the loss in the transmission. Accordingly, Design 2 is not suitable as a bandpass filter.

However, as evident below Design 3 provides an ideal bandpass filter response with flexibility to tune the shape of the response. FIG. 32 shows the spectral response of Design 1 and Design 3 where the coupling coefficients of Design 3 are optimized to achieve the same 3-dB bandwidth of 0.14 nm. For K=0.94 and K₂=0.5 the response of Design 3 is identical to Design 1. The important advantage of Design 3 however is that we can tune the response of the filter to have a box-like response by decreasing the value of K while simultaneously reducing K₂ to keep the same bandwidth. The shape-factor (SF) of the filter, which is defined as the ratio of the 1-dB over the 10-dB bandwidth, can be used to evaluate this box-like behavior. A higher SF means a more box-like response. For K=0.89 and K₂=0.45, the SF increases from 0.34 to 0.38 at the expense of the side-band rejection which decreases from 12 dB to 8 dB. On the other hand, if we increase K from 0.94 to 0.99 and K₂ from 0.5 to 0.6 we can achieve the same bandwidth with a higher side-band rejection of 25 dB at the expense of a smaller SF of 0.25. Therefore, the SR-MZI filter in Design 3 provides additional flexibility for the same order of the filter.

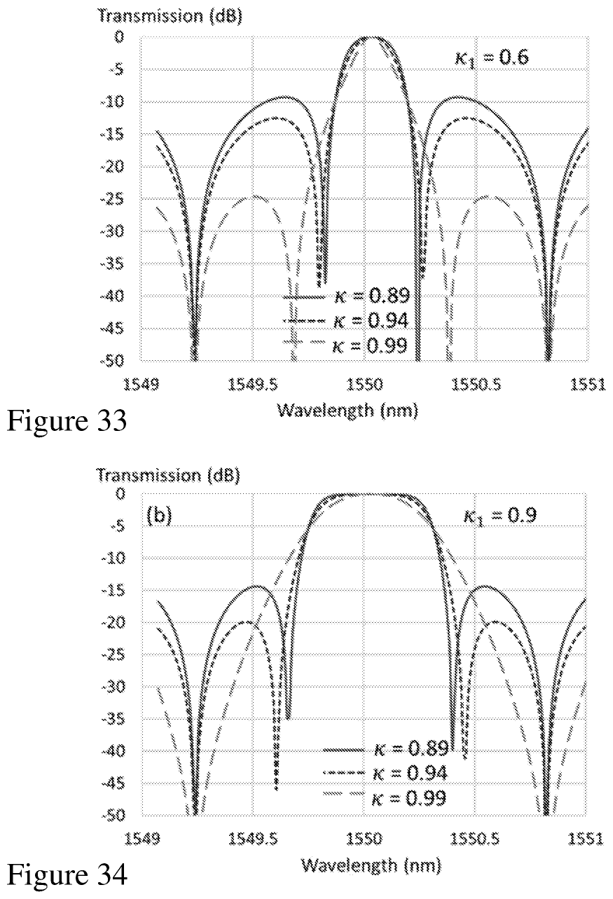

The SR-MZI (Design 3) according to embodiments of the invention provides the required bandpass filter response with flexibility to tune both its shape and side-band rejection. The inventors further investigated its performance by studying the impact of K and K₂ by varying only one coupling coefficient at a time. FIGS. 33 and 34 show the response of the filter when the coupling coefficient K is varied from 0.89 to 0.99 when K₂ is equal to 0.6 and 0.9, respectively. It is evident from FIGS. 33 and 34 that the passband roll-off, which provides the vertical sidewalls of a box-like response, becomes less steep as K increases. Hence, the SF of the filter decreases as K increases. In FIG. 33, the SF is 0.67, 0.60 and 0.36 for K=0.89, 0.94 and 0.99, respectively. Similarly, in FIG. 34, the SF is 0.48, 0.41 and 0.29 for K=0.89, 0.94 and 0.99, respectively. The side-band rejection, on the other hand, increases as K increases. In FIG. 33, the side-band rejection increases from 10 dB at K=0.89 to 25 dB at K=0.99. Similarly, in FIG. 34 the side-band rejection is 15 dB at K=0.89, whereas at K=0.99, there are no side-bands. Therefore, K can be tuned to alter the shape and side-band rejection of the filter. Nevertheless, there is a trade-off between the boxlike shape and the side-band rejection, i.e. improvement in one deteriorates the other.

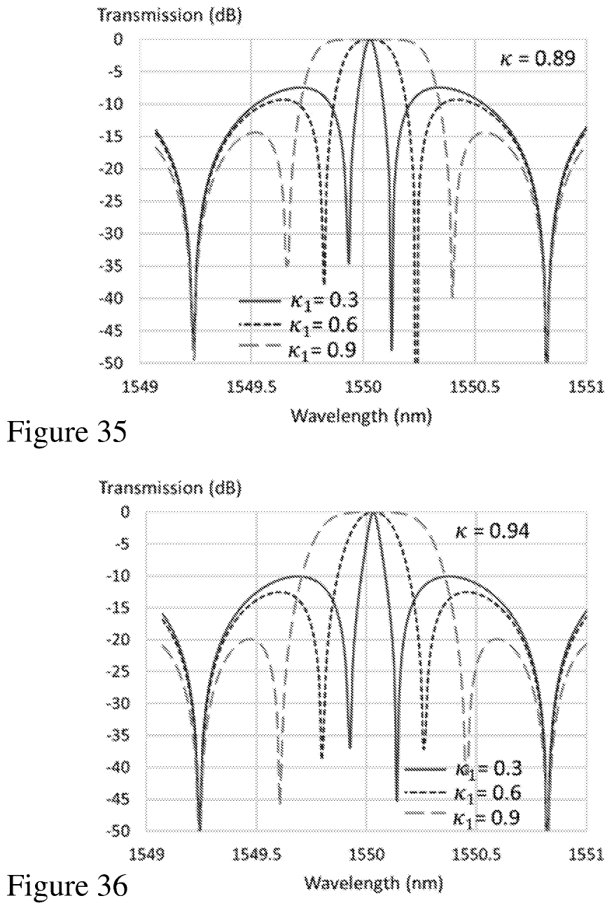

FIGS. 35 and 36 show the response of the filter when the coupling coefficient K₂ is varied from 0.3 to 0.9 and K is 0.89 and 0.94, respectively. It can be observed that the bandwidth and side-band rejection of the filter increases with increasing K₂. In FIG. 35 the 3-dB bandwidths are 0.05 nm, 0.21 nm, and 0.51 nm for K₂=0.3, 0.6 and 0.9, respectively. Similarly, in FIG. 36 the 3-dB bandwidths are 0.05 nm, 0.19 nm, and 0.49 nm for K₂=0.3, 0.6 and 0.9, respectively. Moreover, the side-band rejection increases from around 7 dB to 14 dB in FIG. 35 and from 10 dB to 20 dB in FIG. 36 as K₂ is increased from 0.3 to 0.9. Therefore, K₂ can be tuned to alter the bandwidth of the filter. The minimum achievable bandwidth is limited by the side-band rejection which decreases as K₂ is decreased.

3B. Experimental Results

The inventors implemented filter designs according to embodiments of the invention using ONO waveguides such as described above in respect of Section 2 as fabricated upon a commercial MEMS compatible microfabrication process. This yields trapezoidal SiN cored waveguides with a side-wall angle of approximately 80°. The thickness of the waveguide was 440 nm and the top width, W_{TOP}, was varied from 440 nm to 450 nm and 460 nm to understand the effect of the waveguide width on the filter performance. The fabrication process comprising in an abbreviated sequence:
TEOS Low-Pressure Chemical Vapor Deposition (LPCVD) of a 3.2 μm thick SiO2 layer on the silicon wafer as lower cladding;
Silicon rich SiN layer of 440 nm is deposited using LPCVD for waveguide core;
SiN waveguide patterning using UV stepper lithography and dry etching; and
3.2 μm thick SiO2 cladding deposited using TEOS Plasma Enhanced Chemical Vapor deposition.

It should be noted that the initial devices fabricated did not have a metallization layer on top of the cladding and therefore, did not have heaters to tune the response of these filters by tuning the RRs and MZI using the known techniques of the prior art so that compensations for fabrication variations in the filter can be applied.

As there were no heaters on the fabricated devices the inventors fabricated devices with different spacings between the RRs, and RR1 and MZI to validate their simulation models. The coupling coefficients were evaluated using Finite Difference Time Domain (FDTD). Within these the gap between RR1 and the MZI was fixed at 700 nm, 900 nm, and 1100 nm respectively and the gap between the RRs established at 600 nm, 800 nm, and 1000 nm, respectively. Additionally, the wavelength of the filter can be tuned by simultaneously tuning the phase in the two rings and the MZI.

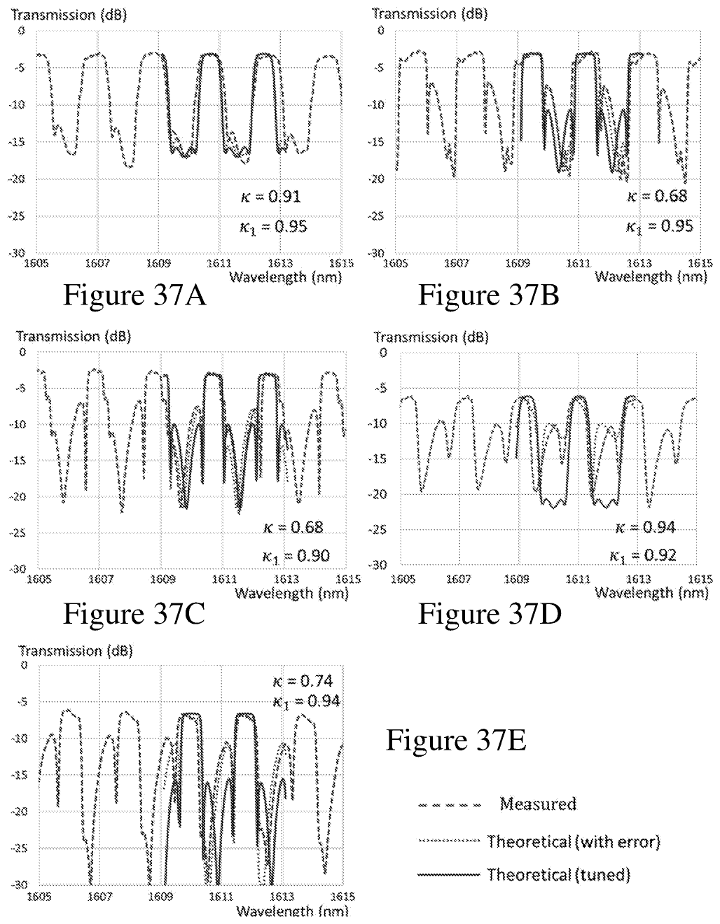

Experimental results for the measured filter response of five devices are presented in FIGS. 37A to 37E respectively wherein:
FIG. 37A W_{TOP}=460 nm;
FIG. 37B W_{TOP}=460 nm;
FIG. 37C W_{TOP}=460 nm;
FIG. 37D W_{TOP}=450 nm; and
FIG. 37E W_{TOP}=440 nm.

The values of K and K₁ were different for each device as shown in FIGS. 37A to 37E respectively and Table 12. It can be observed from the theoretical responses in FIGS. 33 to 36 that the sidebands around the passband are symmetric. However, due to fabrication variations, the phase of the RRs and MZI are non-identical, which leads to asymmetry in the sidebands of the measured responses as shown in FIGS. 37A to 37E, respectively. In addition to the theoretical simulations with no error and experimental results the FIGS. 37A to 37E respectively also include theoretical responses of the filters where errors are introduced in the phase of the RRs or MZI to model the asymmetry due to fabrication variations. The maximum phase error introduced within these simulations to simulate the fabricated devices corresponded to a shift of less than ±2.5 nm in the waveguide width.

TABLE 12
Coupling Strengths to Align Simulations with Experiment Results

| Experiment Results | W_{TOP} | | | Bandwidth |
|---|---|---|---|---|
| FIG. | (nm) | κ | κ₁ | (nm) |
| 37A | 460 | 0.91 | 0.95 | 0.82 |
| 37B | 460 | 0.68 | 0.95 | 0.90 |
| 37C | 460 | 0.68 | 0.90 | 0.54 |
| 37D | 450 | 0.94 | 0.92 | 0.64 |
| 37E | 440 | 0.74 | 0.91 | 0.67 |

In order to evaluate the fabricated devices optical signals were coupled in and out of the photonic circuits using grating couplers. The MZI in the fabricated SR-MZIs employs 3-dB multimode interference (MMI) couplers at the input and output. The extinction ratio of the filters is limited by the splitting ratio of these MMI couplers which can be further optimized for a better performance. The extinction ratio in the theoretical response was also decreased to match the measured response. Accordingly, it should also be noted that the grating couplers provided an optimum response around a wavelength of 1600 nm for the TE mode whilst FIGS. 37A to 37E present measurement results in the wavelength range of approximately 1609 nm to 1613 nm. Since the designs were optimized for λ=1550 nm, the inventors conclude that the filters can provide good performance over a large wavelength range.

Furthermore, the inventors observe that the measured FSR in the experimental devices is slightly higher than the theoretical one which implies that the refractive indices used in the simulation are higher than the actual values. Moreover, some of these devices exhibit a slightly higher bandwidth than expected. It is expected that, due to fabrication variations, the coupling coefficients might differ from the theoretical values presented. However, the inventors found that the shift in coupling coefficients for a variation of ±20 nm in waveguide thickness or width was not significant. The measured bandwidths for the devices whose spectra are presented in FIGS. 37A to 37E respectively, as outlined in Table 12, were 0.82 nm, 0.90 nm, 0.54 nm, 0.64 nm, and 0.67 nm, respectively. The bandwidth variation in these devices justifies the theoretical prediction in the analysis above that an increase in K₁ results in an increase in bandwidth. It can also be observed from FIGS. 37A to 37E that for smaller K values, the response is more box-like compared to a higher K values. Lastly, the inventors also noted that the insertion loss of the devices is higher for devices with smaller waveguide widths. The insertion loss for the devices whose results are presented in Table 12 and FIGS. 37A to 37 respectively with W_{TOP}=460 nm was approximately 3 dB which increased to 6 dB for the device with W_{TOP}=450 nm in FIG. 37D and 6.5 dB fOr the device with W_{TOP}=440 nm in FIG. 37E. These increased insertion losses are believed to arise from higher scattering losses in the narrower waveguides.

3C: Tuning of SR-MZI Filters

As evident from the analysis in Section 3A the bandwidth, shape, and wavelength of SR-MZI filters according to embodiments of the invention can be tuned to implement full reconfigurability. The bandwidth and shape of the filter can be tuned simply by changing the strength of coupling between the two rings, and between RR1 and MZI, respectively. On the other hand, the wavelength of the filter can be tuned by simultaneously adjusting the phases of the two rings and the MZI.

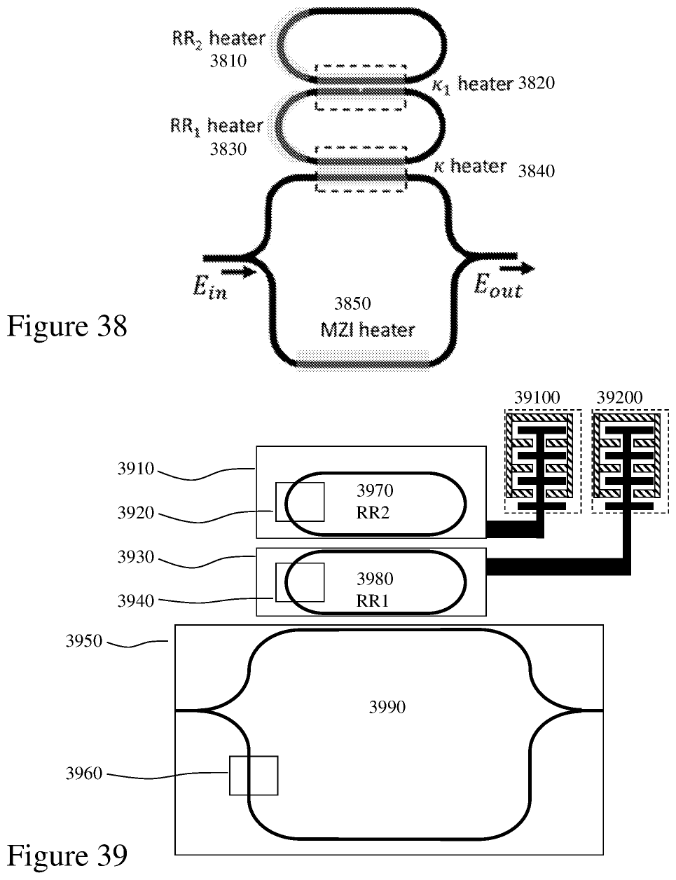

Referring to FIG. 38A there is depicted an SR-MZI according to an embodiment of the invention wherein a series of heaters are employed on the top of the RRs and the MZI and at the coupling regions. These being:
First heater 3810 to adjust phase within RR;
Second heater 3820 to adjust coupling strength between RR and RR₁;
Third heater 3830 to adjust the phase within RR₁;
Fourth heater 3840 to adjust the coupling strength between arm of the MZI and RR₁; and
Fifth heater 3850 to adjust the phase of the MZI

The coupling between the RRs or RR and MZI reduces with increased power dissipated from the heaters. These heaters can be used to thermally tune the bandwidth, shape and wavelength in the filter as described above. However, as noted above with respect to Sections 1 and 2 thermal actuated elements result in complex control algorithms to compensate for thermal crosstalk within the same photonic circuit element, e.g. the five heaters within the SR-MZI, as well as thermal crosstalk from other photonic circuit elements.

Accordingly, the inventors also have established a design methodology according to embodiments of the invention as depicted in FIG. 39 wherein the SR-MZI comprises:
a first movable platform 3910 coupled to a first MEMS actuator 39100 wherein RR₂ 3970 is formed upon the first movable platform 3910;
a second movable platform 3930 coupled to a second MEMS actuator 39200 wherein
RR₁ 3980 is formed upon the second movable platform 3930; and
a fixed platform 3950 upon which is formed the MZI 3990.

Accordingly, using first and second MEMS actuators 39100 and 39200 respectively the first and second movable platforms 3910 and 3930 can be moved relative to each other and the fixed platform 3950 allowing the coupling strengths between the MZI 3990 and RR1 3980 and between RR1 2980 and RR2 3970 to be adjusted. Optionally, the first MEMS actuator 39100 and RR1 3970 may formed upon a movable platform nested within second movable platform 3930 or vice-versa.

Also forming part of the first movable platform 3910 and RR2 3970 is a first phase shift element 3920 and forming part of the second movable platform 3930 and RR1 3980 is a second phase shift element 3940. The MZI 3990 further includes a third phase shift element 3960. Each of the first to third phase shift elements 3920, 3940 and 3960 may exploit thermal tuning as outlined above in respect of FIG. 38 or they may alternatively exploit analog and/or digital MEMS actuated perturbation elements such as described and depicted in respect of FIGS. 5 to 27H respectively providing a full MEMS based solution to phase shift adjustments and coupling strength adjustments. As noted above such a MEMS based solution allows reduced power consumption, eliminates thermal crosstalk issues, and allows for latched actuation such that once tuned the MEMS actuators are not powered.

Whilst the embodiments of the invention described and depicted above in respect of FIGS. 1 to 39 have been described and depicted with respect to asymmetric cladding it would be evident that embodiments of the invention may no asymmetry (i.e. symmetric) or with low asymmetry without departing from the scope of the invention where the perturbation is not applied to a waveguide requiring inherent asymmetry to provide the required mode(s) or hybrid mode(s) of the optical waveguide being perturbed. For example, referring to first image 4000A a perturbation element is depicted in disposed on one side of an optical waveguide with symmetric cladding. As noted above this sidewall cladding may be zero or as described above in respect of its thickness. Accordingly, referring to second image 4000B such symmetric thin or no cladding may be employed in conjunction with a pair of perturbation elements disposed either side of the optical waveguide. Hence, for a phase shifting perturbation double the phase shift of a single perturbation element may be induced in respect of such a structure. It would also be evident that whilst the embodiments of the invention above have been described with respect to perturbation elements on one side of an optical waveguide that perturbation elements may be disposed on one or both sides according to geometric layout considerations even where asymmetric cladding is employed in the regions with perturbation elements. Further, as depicted in third image 4000C in FIG. 40 a variant of the design described and depicted in respect of FIG. 26 is presented wherein the optical waveguide has no side cladding on either side but has the overhang structure. This may be further extended as depicted in fourth image 4000D in FIG. 40 wherein the symmetric overhang optical waveguide is disposed between a pair of perturbation elements upon MEMS actuators. Accordingly, if the perturbation elements were digital designs then the structures in second and fourth images 4000B and 4000D would provide for perturbations of 0, X and 2X in the optical waveguide. If the perturbation elements were digital designs then the structures in second and fourth images 4000B and 4000D would provide for continuous perturbations between 0 and 2Y where Y is the maximum perturbation of a single perturbation element. Within other embodiments of the invention the left and right side perturbation elements may have different gaps and/or lengths such that the maximum perturbation induced was different on one side to the other side.

Whilst the embodiments of the invention described and depicted above in respect of FIGS. 1 to 39 have been described and depicted with respect to linear electrostatic comb actuators it would be evident that other electrostatic actuators may be employed including, but not limited to, linear parallel plate actuators, rotational electrostatic comb actuators, rotational parallel plate actuators, and MEMS based inch-worm drives.

Further, whilst embodiments of the invention have been described with respect to electrostatic actuation it would be evident that other actuation means/mechanisms may be employed within other embodiments of the invention including, but not limited to, piezoelectric, magnetic, and thermal.

Embodiments of the invention may further incorporate other MEMS elements allowing additional functionality or features to be implemented. For example, MEMS elements may grip or lock the MEMS actuator such that long term actuation of the actuator is not required. For example, a gripping structure may be actuated to allow the actuator to move and then once set to the desired point the gripping structure de-actuated to re-grip. Alternatively, a tooth or teeth on the MEMS actuator may be selectively engaged with other teeth upon a locking actuator so that the locking actuator is engaged to separate its teeth from those on the actuator, the actuator adjusted, and then the locking actuator de-actuated to relock its teeth with those on the actuator.

Within the embodiments of the invention described above the optical waveguides have been described as exploiting a silicon core upon a silicon dioxide SiO₂ cladding, i.e. a Si—SiO₂ waveguide structure. However, it would be evident that embodiments of the invention may also be employed in conjunction with other waveguide materials systems. These may include, but not be limited to:
a silicon nitride core with silicon oxide upper and lower cladding, a SiO₂—Si₃N₄—SiO₂ waveguide structure;
a silicon core and silicon nitride lower cladding, a Si—Si₃N₄ waveguide structure;
a silicon core and silicon nitride upper and lower claddings, a Si₃N₄—Si—Si₃N₄ waveguide structure;
a silicon core with silicon oxide upper and lower claddings, a SOI waveguide, e.g. SiO₂—Si—SiO₂;
a doped silica core relative to undoped cladding, a SiO₂-doped_SiO₂—SiO₂, e.g. germanium doped (Ge) yielding SiO₂—Ge:SiO₂—SiO₂;
a silicon core and silicon oxynitride upper and lower claddings, a SiOₓN_{y}—Si—SiOₓN_{y} waveguide structure;
silicon oxynitride core with silicon oxide upper and lower claddings, a SiO₂—SiOₓN_{y}—SiO₂ waveguide structure;
polymer-on-silicon; and
doped silicon waveguides.

Additionally, waveguide structures without upper claddings may be employed. However, it would be evident to one skilled in the art that the embodiments of the invention may be employed in a variety of waveguide coupling structures coupling onto and/or from waveguides employing material systems that include, but not limited to, SiO₂—Si₃N₄—SiO₂; SiO₂—Ge:SiO₂—SiO₂; Si—SiO₂; ion exchanged glass, ion implanted glass, polymeric waveguides, indium gallium arsenide phosphide (InGaAsP), InP, GaAs, III-V materials, II-VI materials, Si, SiGe, and single mode optical waveguides and multimode optical waveguides.

Whilst the embodiments of the invention have been described and depicted with respect to silicon material system supporting monolithic integration of the optical waveguides and MEMS actuators it would be evident that other embodiments of the invention may employ discrete actuators or hybrid integration methodologies.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

1. An optical device comprising:
an input waveguide section;
an output waveguide section; and
a central waveguide section disposed between the input waveguide section and the output waveguide section; wherein
a cladding of the central waveguide section is disposed with respect to a core of the central waveguide section such that the core is close to a side wall of the cladding.

2. The optical device according to claim 1, wherein
a width of the cladding on one side of the core of the central waveguide section is established such that a first fraction of a first hybrid mode of the central waveguide section and a second fraction of second hybrid mode of the central waveguide section are equal such that after a predetermined length an optical signal launched with a first polarisation is rotated to a second polarisation orthogonal to the first polarisation.

3. The optical device according to claim 1, further comprising:
a microelectromechanical systems (MEMS) element comprising:
a suspended platform;
a MEMS actuator coupled to the suspended platform; and
a perturbation element disposed at a distal end of the suspended platform to that coupled to the MEMS actuator; wherein
the perturbation element is disposed beside the side wall of the cladding to which the core is close.

4. The optical device according to claim 3, wherein
a width of the cladding on one side of the core of the central waveguide section is established such that a first fraction of a first hybrid mode of the central waveguide section exceeds a second fraction of second hybrid mode of the central waveguide section; and
adjustment of a gap between the perturbation element and the side wall of the cladding to which the core is close perturbs the central waveguide section such that the first fraction and second fraction are equal and after the predetermined length of the central waveguide section an optical signal coupled from the input waveguide section to the central waveguide section with a first polarisation is rotated to a second polarisation orthogonal to the first polarisation and coupled to the output waveguide section.

5-6. (canceled)

7. An optical waveguide phase shift element comprising:
a waveguide section comprising:
an input waveguide section;
an output waveguide section; and
a central waveguide section of a predetermined length disposed between the input waveguide section and the output waveguide section having a cladding disposed with respect to a core of the central waveguide section such that the core is either close to a side wall of the cladding or exposed through the cladding; and
a microelectromechanical systems (MEMS) element comprising:
a suspended platform;
a MEMS actuator coupled to the suspended platform; and
a perturbation element disposed at a distal end of the suspended platform to that coupled to the MEMS actuator; wherein
the perturbation element is disposed beside the side wall of the cladding to which the core is close to or exposed through.

8. The optical waveguide phase shift element according to claim 7, wherein adjustment of a gap between the perturbation element and the core of the central waveguide section perturbs the central waveguide portion inducing a phase shift in an optical signal propagating within the central waveguide section.

9. The optical waveguide phase shift element according to claim 7, wherein the MEMS element employs a linear spring or a non-linear spring.

10. The optical waveguide phase shift element according to claim 7, wherein the MEMS element allows continuous adjustment of a gap between the perturbation element and the core of the central waveguide section such that a perturbation applied to the central waveguide portion is continuously adjustable thereby inducing a variable phase shift in an optical signal propagating within the central waveguide section.

11. The optical waveguide phase shift element according to claim 7, wherein the MEMS element is driven from a first state to a second state or vide-versa;
such that a gap between the perturbation element and the core of the central waveguide section is adjusted from a first predetermined value to a second predetermined value less than the first predetermined value;
in the first state a gap between the perturbation element and the core of the central waveguide section is large enough that no or minimal perturbation is applied to the central waveguide portion by the perturbation element;
in the second state the gap between the perturbation element and the core of the central waveguide section is reduced to a predetermined value such that a perturbation is applied to the central waveguide portion by the perturbation element thereby inducing a predetermined phase shift in an optical signal propagating within the central waveguide section.

12. The optical waveguide phase shift element according to claim 7, wherein the predetermined value of the gap in the second state is zero.

13. The optical waveguide phase shift element according to claim 7, wherein the predetermined value of the gap is non-zero; and
the gap is defined by one or more mechanical stoppers which limit movement of the perturbation element relative to the central waveguide section.

14. The optical waveguide phase shift element according to claim 7, wherein in the second state the MEMS element is actuated to induce pull-in; and
the optical waveguide phase shift element acts as a digital element applying either no phase shift in the first state or the predetermined phase shift in the second state.

15. The optical waveguide phase shift element according to claim 7, wherein the optical waveguide phase shift element is one of a plurality of optical waveguide phase shift elements;
each optical waveguide phase shift element of the plurality of optical waveguide phase shift elements has a different length over which the perturbation element perturbs the central waveguide section; and
the different lengths form a binary sequence such that for N optical waveguide phase shift elements the overall phase shift applied can be set to one of 2N phase shifts.

16. The optical waveguide phase shift element according to claim 7, wherein the MEMS actuator is an electrostatic parallel plate actuator.

17-19. (canceled)

20. An optical device comprising:
a tunable optical filter comprising:
a Mach-Zehnder interferometer (MZI);
a first ring resonator; and
a second ring resonator disposed between an arm of the MZI and the first ring resonator such that optical signals coupled to the MZI are only coupled to the first ring resonator via the second ring resonator; wherein
a bandwidth of the tunable optical filter is established in dependence upon a first coupling strength between the arm of the MZI and a second coupling strength between the first ring resonator and the second ring resonator;
a shape of the passband of the tunable optical filter is established in dependence upon the first coupling strength and the second coupling strength; and
the centre wavelength of the tunable optical filter is established in dependence upon a first phase shift within the MZI, a second phase shift within the first ring resonator and a second phase shift within the second ring resonator.

21. The optical device according to claim 20, wherein
the MZI is formed upon a fixed portion of a substrate;
the first ring resonator is formed upon a first movable platform movable relative to the substrate under the action of a first microelectromechanical systems (MEMS) actuator;
the second ring resonator is formed upon a second movable platform movable relative to the substrate under the action of a second microelectromechanical systems (MEMS) actuator; and
the first coupling strength and the second coupling strength can be adjusted by appropriate actuation of the first MEMS actuator and the second MEMS actuator.

22. The optical device according to claim 20, wherein either:
the second movable platform is nested within the first movable platform and the second MEMS actuator moves the second movable platform relative to the first movable
platform and the first MEMS actuator moves both the first movable platform and the second movable platform relative to the arm of the MZI;
or:
the first movable platform is nested within the second movable platform and the first MEMS actuator moves the first movable platform relative to the second movable platform and the second MEMS actuator moves both the first movable platform and the second movable platform relative to the arm of the MZI.

23. The optical device according to claim 20, wherein
the first movable platform and the second movable platform are movable independent of one another relative to the fixed portion of the substrate.

24. The optical device according to claim 20, wherein
the first phase shift is adjustable under the action of a first phase shift element;
the second phase shift is adjustable under the action of a second phase shift element;
the third phase shift is adjustable under the action of a third phase shift element; and
each of the first phase shift element, the second phase shift element, and the third phase shift element comprise:
a waveguide section comprising:
an input waveguide section;
an output waveguide section; and
a central waveguide section of a predetermined length disposed between the input waveguide section and the output waveguide section having a cladding disposed with respect to a core of the central waveguide section such that the core is either close to a side wall of the cladding or exposed through the cladding; and
a microelectromechanical systems (MEMS) element comprising:
a suspended platform;
a MEMS actuator coupled to the suspended platform; and
a perturbation element disposed at a distal end of the suspended platform to that coupled to the MEMS actuator; and
each perturbation element is disposed beside the side wall of the cladding to which the core is close to or exposed through.

25. (canceled)
